(19) United States
(12) Patent Application Publication
(10) Pub. No.: US 2011/0155057 A1
(43) Pub. Date: Jun. 30, 2011

(54) PLASMA PROCESS APPARATUS

(75) Inventors: Hitoshi KATO, Iwate (JP); Tatsuya Tamura, Iwate (JP); Shigehiro Ushikubo, Iwate (JP); Hiroyuki Kikuchi, Iwate (JP)

(73) Assignee: TOKYO ELECTRON LIMITED

(21) Appl. No.: 12/975,355

(22) Filed: Dec. 22, 2010

(30) Foreign Application Priority Data
Dec. 25, 2009 (JP) 2009-295110
Jun. 17, 2010 (JP) 2010-138669

(51) Int. Cl. C23C 16/44; C23C 16/505

(52) U.S. Cl. 118/719; 118/723 R; 118/723 I

(57) ABSTRACT

A plasma process apparatus for processing a substrate by using plasma including a vacuum chamber in which the processing of the substrate is performed, a turntable inside the vacuum chamber, the turntable having at least one substrate receiving area, a rotation mechanism rotating the turntable, a gas supplying part supplying plasma generation gas to the substrate receiving area, a main plasma generating part ionizing the plasma generation gas, being provided in a position opposite to a passing area of the substrate receiving area, and extending in a rod-like manner from a center portion of the turntable to an outer circumferential portion of the turntable, an auxiliary plasma generating part compensating for insufficient plasma of the main plasma generating part, the auxiliary plasma generating part being separated from the main plasma generating part in a circumferential direction of the vacuum chamber, and an evacuating part evacuating the vacuum chamber.

### CROSS-REFERENCE TO RELATED APPLICATION

This application claims the benefit of priority of Japanese Patent Application Nos. 2009-295110 and 2010-138669, filed on Dec. 25, 2009 and Jun. 17, 2010 with the Japanese Patent Office, respectively, the entire content of which is hereby incorporated by reference.

### BACKGROUND OF THE INVENTION

1. Field of the Invention

The present invention relates to a plasma process apparatus for processing plasma inside a vacuum chamber by using plasma.

2. Description of the Related Art

There has been known a film deposition apparatus where a film deposition process is performed while plural substrates such as semiconductor wafers placed on a turntable are rotated in relation to a reaction gas supplying portion, as an apparatus for performing a film deposition method that deposits a film on the substrates employing the reaction gas under a U.S. Pat. No. 7,153,542, Japanese Patent Publication No. 3,144,664, and U.S. Pat. No. 6,634,314 describe film deposition apparatuses of so-called mini-batch type that are configured so that plural kinds of reaction gases are supplied from reaction gas supplying portions to the substrates and the reaction gases are separated by, for example, providing partition members between areas where the corresponding gases are supplied, or ejecting inert gas to create a gas curtain between the areas, thereby reducing intermixture of the reaction gases. By using such an apparatus, an Atomic Layer Film deposition (ALD) or Molecular Layer Film deposition (MLD) where a first reaction gas and a second reaction gas are alternately supplied to the substrates is performed.

When performing deposition of a thin film by using the ALD (MLD) method, impurities (e.g., organic substances and water vapor) contained in the reaction gas may be absorbed in the thin film due to low deposition temperature. In order to remove the impurities and form a consolidated thin film with few impurities, it is necessary to perform a subsequent process (e.g., reforming process using plasma) on the wafer. However, performing such subsequent process on plural layers of thin films increases the number of steps and increases cost. Although there is a method of performing the subsequent process inside the vacuum chamber, it would be necessary to rotate a plasma generating portion for generating plasma and a reaction gas supplying portion relative to a pedestal. Thus, there occurs a time difference for a wafer to contact the plasma with respect to a radial direction of the pedestal. Thus, the degree of reformation does not match between that of the center side and that of the outer circumferential side of the pedestal. In such a case, film property and film thickness may become inconsistent inplane of the wafer, or the wafer may be partially damaged. Further, in a case where a large amount of electric power is supplied to the plasma generating portion, there is a risk that the plasma generating portion could quickly degrade.

### SUMMARY OF THE INVENTION

The present invention has been made in view of the above, and provides a plasma process apparatus.

A first aspect of the present invention provides a plasma process apparatus for processing a substrate by using plasma, the plasma process apparatus including: a vacuum chamber in which the processing of the substrate is performed; a turntable provided inside the vacuum chamber, the turntable having at least one substrate receiving area on which the substrate is received; a rotation mechanism that rotates the turntable; a gas supplying part that supplies a plasma generation gas to the substrate receiving area; a main plasma generating part that ionizes the plasma generation gas by applying energy to the plasma generation gas, the main plasma generating part being provided in a position opposite to a passing area of the substrate receiving area and extending in a rod-like manner from a center portion of the turntable to an outer circumferential portion of the turntable; an auxiliary plasma generating part that compensates for insufficient plasma of the main plasma generating part, the auxiliary plasma generating part being separated from the main plasma generating part in a circumferential direction of the vacuum chamber; and an evacuating part that evacuates the inside of the vacuum chamber.

### BRIEF DESCRIPTION OF THE DRAWINGS

FIG. 1 is a vertical cross-sectional view of a film deposition apparatus (plasma process apparatus) according to an embodiment of the present invention taken along line I-I′ of FIG. 3;

FIG. 2 is a perspective view illustrating an inner configuration of a film deposition apparatus according to an embodiment of the present invention;

FIG. 3 is a horizontal cross-sectional view of a film deposition apparatus according to an embodiment of the present invention;

FIG. 4 is a vertical cross-sectional view illustrating a partial inner configuration of a film deposition apparatus according to an embodiment of the present invention;

FIG. 5 is another vertical cross-sectional view illustrating a partial inner configuration of a film deposition apparatus according to an embodiment of the present invention;

FIGS. 6A and 6B are perspective views of an activated gas injector according to an embodiment of the present invention;

FIG. 7 is a vertical cross-sectional view illustrating an example of an activated gas injector provided in a film deposition apparatus according to an embodiment of the present invention;

FIG. 8 is a vertical cross-sectional view illustrating an activated gas injector of a film deposition apparatus according to an embodiment of the present invention;

FIG. 9 is a vertical cross-sectional view for describing measurements of an activated gas injector according to an embodiment of the present invention;

FIG. 10 is a schematic view for describing concentration of plasma generated in an activated gas injector according to an embodiment of the present invention;

FIG. 11 is a schematic diagram for describing the state of a thin film, formed with a reforming process using a film deposition apparatus according to an embodiment of the present invention;

FIG. 12 is for describing the flow of gas in a film deposition apparatus according to an embodiment of the present invention;

FIG. 13 is a perspective view of a film deposition apparatus according to another embodiment of the present invention;

FIG. 14 is a perspective view of a film deposition apparatus according to another embodiment of the present invention;

FIG. 15 is a plan view of a film deposition apparatus according to another embodiment of the present invention;

FIG. 16 is a plan view of a film deposition apparatus according to another embodiment of the present invention;

FIG. 17 is a schematic plan view of a reforming apparatus according to an embodiment of the present invention;

FIG. 18 is a plan view illustrating a film deposition apparatus according to another embodiment of the present invention;

FIG. 19 is a plan view illustrating a film deposition apparatus according to another embodiment of the present invention;

FIG. 20 is a cross-sectional view of a film deposition apparatus according to another embodiment of the present invention;

FIG. 21 is a schematic view illustrating a film deposition apparatus according to an embodiment of the present invention;

FIG. 22 is a perspective view illustrating a film deposition apparatus according to another embodiment of the present invention;

FIG. 23 is a perspective view illustrating a film deposition apparatus according to another embodiment of the present invention;

FIG. 24 is a side view illustrating a film deposition apparatus according to another embodiment of the present invention;

FIG. 25 is a front view illustrating a film deposition apparatus according to another embodiment of the present invention;

FIG. 26 is a schematic diagram illustrating a film deposition apparatus according to another embodiment of the present invention;

FIG. 27 is a perspective view illustrating a film deposition apparatus according to another embodiment of the present invention;

FIG. 28 is a cross-sectional view illustrating a film deposition apparatus according to another embodiment of the present invention;

FIG. 29 is a cross-sectional view illustrating a film deposition apparatus according to another embodiment of the present invention;

FIG. 30 is a table illustrating characteristics obtained with a film deposition apparatus according to an embodiment of the present invention;

FIG. 31 is a table illustrating characteristics obtained with a film deposition apparatus according to an embodiment of the present invention;

FIGS. 32A-32G are schematic diagrams illustrating characteristics obtained with a film deposition apparatus according to an embodiment of the present invention;

FIGS. 33A-33B are schematic diagrams illustrating characteristics obtained with a film deposition apparatus according to an embodiment of the present invention;

FIGS. 34A and 34B are schematic diagrams illustrating characteristics obtained with a film deposition apparatus according to an embodiment of the present invention;

FIGS. 35A-35D are schematic diagrams illustrating characteristics obtained with a film deposition apparatus according to an embodiment of the present invention;

FIG. 36 is a schematic diagram illustrating characteristics obtained with a film deposition apparatus according to an embodiment of the present invention;

FIG. 37 is a plan view illustrating a film deposition apparatus according to an embodiment of the present invention;

FIG. 38 is a table illustrating characteristics obtained with a film deposition apparatus according to an embodiment of the present invention;

FIG. 39 is a plan view illustrating a film deposition apparatus according to an embodiment of the present invention;

FIG. 40 is a graph illustrating characteristics obtained with a film deposition apparatus according to an embodiment of the present invention;

FIG. 41 is a schematic view for describing results obtained with a film deposition apparatus according to an embodiment of the present invention;

FIGS. 42A-42C are plan views illustrating a film deposition apparatus according to an embodiment of the present invention;

FIG. 43 is a graph illustrating characteristics obtained with a film deposition apparatus according to an embodiment of the present invention;

FIG. 44 is a table illustrating characteristics obtained with a film deposition apparatus according to an embodiment of the present invention; and

FIG. 45 is a graph illustrating characteristics obtained with a film deposition apparatus according to an embodiment of the present invention.

### DETAILED DESCRIPTION OF THE PREFERRED EMBODIMENT

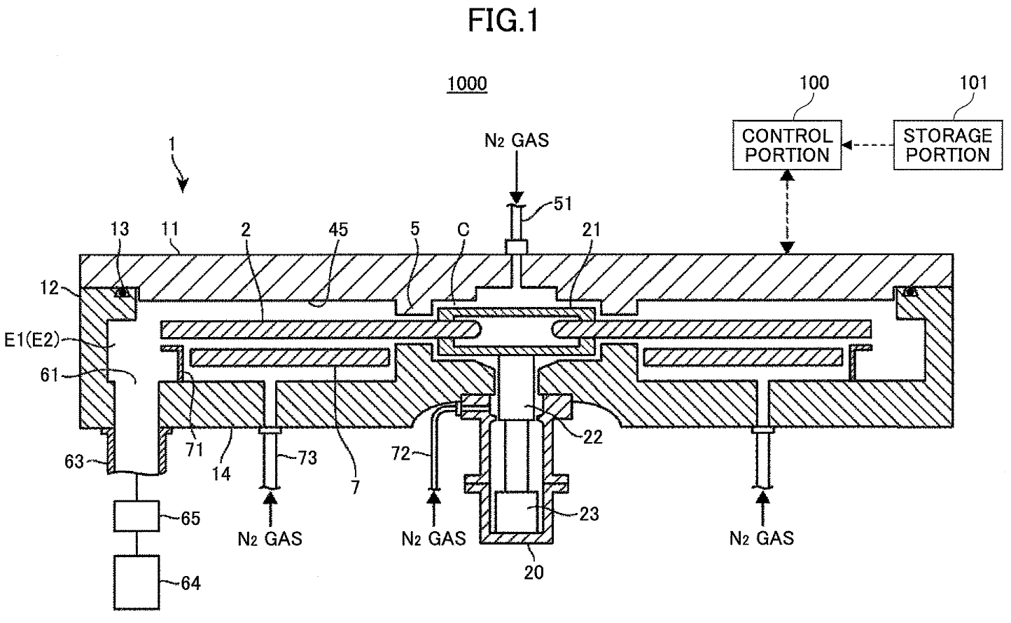

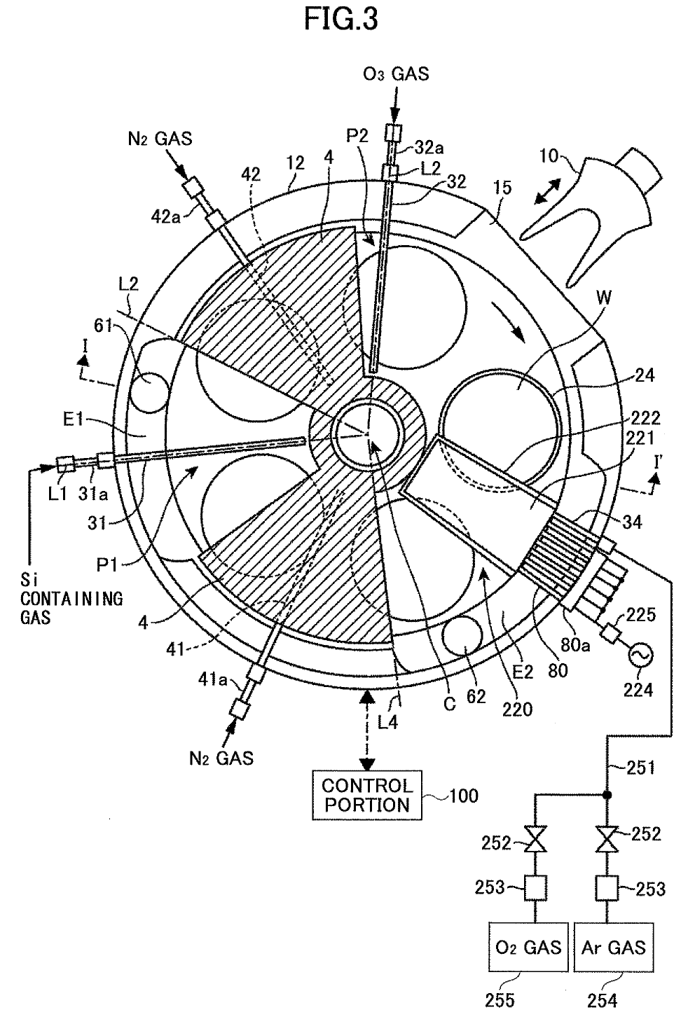

As an example of a plasma process apparatus according to an embodiment of the present invention, FIG. 1 (cross-sectional view taken along line I-I′ of FIG. 3) illustrates a configuration of a film deposition apparatus (plasma process apparatus) 1000. The film deposition apparatus 1000 has a vacuum chamber 1 having a flattened cylinder top view shape, and a turntable 2 that is located inside the vacuum chamber 1 and has a rotation center in a center of the vacuum chamber 1. The vacuum chamber 1 has a chamber body 12 from which a ceiling plate 11 can be separated. The ceiling plate 11 is hermetically attached on the chamber body 12 by reduced pressure therein via a sealing member such as an O-ring 13 provided on an upper end plane of the chamber body 12. The ceiling plate 11 can be moved upward by a driving mechanism (not shown) when separating from the chamber body 12.

The turntable 2 is attached at its center onto a cylindrically shaped core portion 21. The core portion 21 is fixed on a top end of a rotational shaft 22 that extends in a vertical direction. The rotational shaft 22 penetrates a bottom portion 14 of the vacuum chamber 1 and is fixed at the lower end to a driving mechanism 23 that can rotate the rotational shaft 22 clockwise in this embodiment. The rotational shaft 22 and the driving mechanism 23 are housed in a case body 20 having a cylinder with a bottom. The case body 20 is hermetically fixed to a bottom surface of the bottom portion 14 of the vacuum chamber 1 via a flange portion, which isolates an inner environment of the case body 20 from an outer environment.

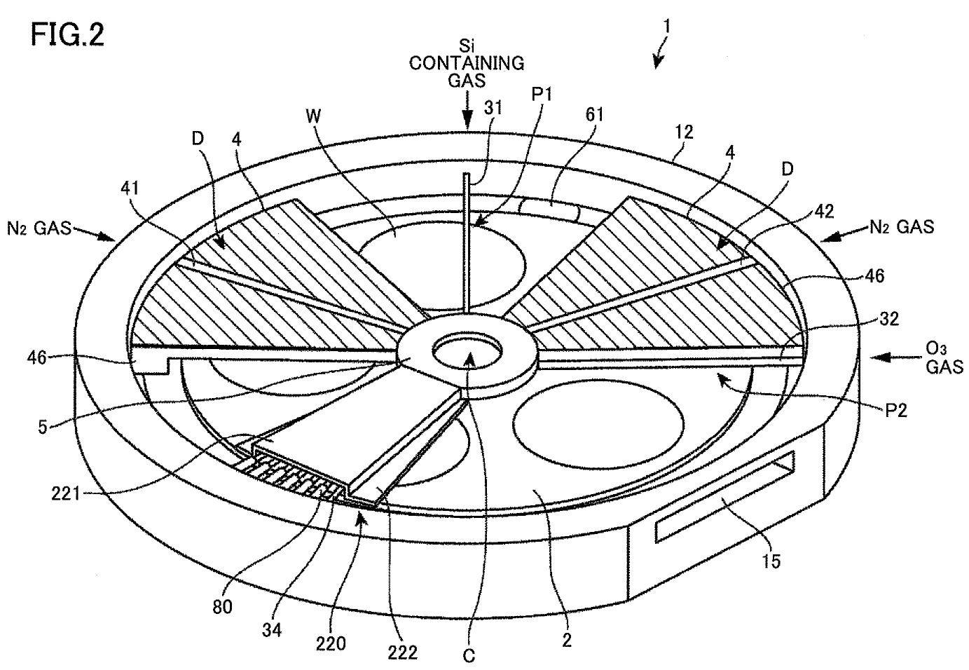

As shown in FIGS. 2 and 3, plural (e.g., five) circular concave portions 24, each of which receives a semiconductor wafer (referred to as wafer below) W, are formed in a top surface of the turntable 2 along a rotation direction (circumferential direction). Incidentally, only one wafer W placed at one of the concave portions is illustrated in FIG. 3, for the sake of convenience. The concave portion 24 has a diameter slightly larger, for example, by 4 mm than the diameter of the wafer W and a depth equal to a thickness of the wafer W. Therefore, when the wafer W is placed in the concave portion 24, a surface of the wafer W and a surface of the turntable 2 (area where the wafer W is not received) form substantially the same plane. In the bottom of the concave portion 24, there are formed three through holes (not shown) through which three corresponding elevation pins are raised/lowered. The elevation pins support a back surface of the wafer W and raise/lower the wafer W. The concave portions 24 are wafer W receiving areas provided to position the wafers W and prevent the wafers W from being thrown outwardly by centrifugal force caused by rotation of the turntable 2. The concave portions 24 serve as substrate receiving areas according to an embodiment of the present invention.

As shown in FIGS. 2 and 3, first and second reaction gas nozzles 31, 32 (formed of, for example, quartz), two separation gas nozzles 41, 42, and an activated gas injector 220 are provided at angular intervals along the circumferential direction of the vacuum chamber 1 (rotation direction of the turntable 2) at positions facing the passing areas of the concave portions 24 of the turntable 24. In the illustrated example, the activated gas injector 220, the separation gas nozzle 41, the first reaction gas nozzle 31, the separation gas nozzle 42, and the second reaction gas nozzle 32 are arranged in this order along a clockwise direction from a transfer opening 15 (described below). The activated gas injector 220 and the nozzles 31, 32, 41, 42 are attached in a manner horizontally extending in a direction from the circumferential wall of the vacuum chamber 1 to the rotation center of the turntable 2 and in a manner facing the wafer W. The base ends of the nozzles 31, 32, 41, 42, which are gas inlet ports 31a, 32a, 41a, 42a, respectively, penetrate the circumferential wall of the vacuum chamber 1. The first reaction gas nozzle 31 serves as a first reaction gas supplying portion, and the reaction gas nozzle 32 serves as a second reaction gas supplying portion. The separation gas nozzles 41, 42 serve as separation gas supplying portions. The activated gas injector 220 is described in detail below.

The first reaction gas nozzle 31 is connected to a gas supplying source of diisopropyl aminosilane gas, which is a first reaction gas containing silicon (Si), via a flow rate adjustment valve or the like (not illustrated). The second reaction gas nozzle 32 is connected to a gas supplying source of a mixed gas of oxygen (O₂) and ozone (O₃) gas, which is a second reaction gas, via a flow rate adjustment valve or the like (not illustrated). The separation gas nozzles 41, 42 are connected to gas supplying sources of N₂ (nitrogen) gas (not illustrated), which serves as a separation gas. Incidentally, the second reaction gas is O₃ gas for the sake of convenience.

The first and second reaction gas nozzles 31, 32 have ejection holes 33 facing downward and arranged in longitudinal directions of the reaction gas nozzles 31, 32 at intervals of, for example, about 10 mm in this embodiment. An area below the first reaction gas nozzle 31 may be referred to as a first process area P1 in which the Si containing gas is adsorbed on the wafer W, and an area below the second reaction gas nozzle 32 may be referred to as a second process area P2 in which the O₃ gas is adsorbed on the wafer W.

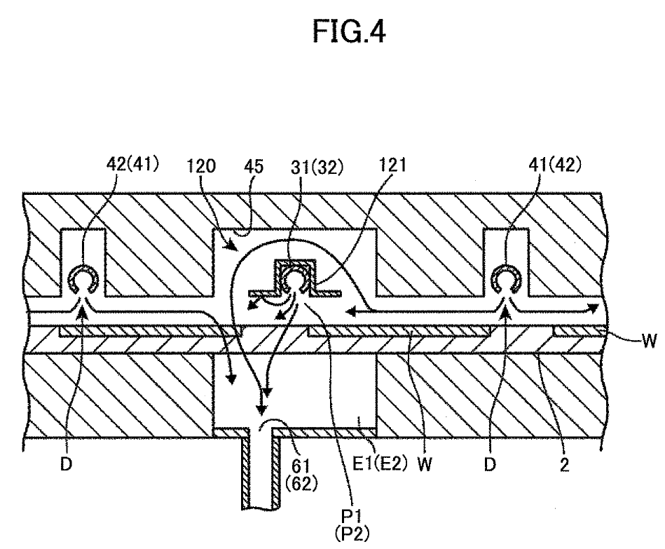

Although not illustrated in FIGS. 1-3, the reaction nozzles 31, 32 are separated from a ceiling surface 45 of the process areas P1, P2 and provided close to the wafer W, respectively, as illustrated in FIG. 4. Further, a nozzle cover 120 being open downward and covering an upper part of the reaction nozzles 31, 32 in the longitudinal direction of the reaction nozzles 31, 32. A large portion of separation gas flows from a lower end side of the nozzle cover 120 along a longitudinal direction of the nozzle cover 120 to a portion between a flow regulatory plate 121 and the ceiling surface 45 extending in both directions in a circumferential direction of the turntable 2. Hardly any separation gas flows between the turntable 2 and the reaction gas nozzle 31 (32). Therefore, the density of the reaction gas supplied from the reaction gas nozzle 31 (32) in each process area P1, P2 can be prevented from decreasing. Thus, deposition to the surface of the wafer W can be performed efficiently.

The separation gas nozzles 41, 42 are provided in separation areas D that are configured to separate the first process area P1 and the second process area P2. In each of the separation areas D, there is provided a convex portion 4 on the ceiling plate 11, as shown in FIGS. 2 and 3. The convex portion has a top view shape of a truncated sector and is protruded downward from the ceiling plate 11. The inner (or top) arc is coupled with the protrusion portion 5 and an outer (or bottom) arc lies near and along the inner circumferential wall of the vacuum chamber 1. In addition, the convex portion 4 has a groove portion 43 that extends in the radial direction and substantially bisects the convex portion 4. The separation gas nozzles 41, 42 are located in the corresponding groove portions 43.

With the above configuration, there are flat low ceiling surfaces 44 (first ceiling surfaces) on both sides of the separation gas nozzles 41, 42, and high ceiling surfaces 45 (second ceiling surfaces, higher than the low ceiling surfaces 44) outside of the corresponding low ceiling surfaces 44. The convex portion 4 (ceiling surface 44) provides a separation space, which is a thin space, between the convex portion 4 and the turntable 2 in order to impede the first and the second reaction gases from entering the thin space and from being mixed. For example, with respect to the separation gas nozzle 41, O₃ gas is impeded from entering from an upstream side relative to a rotation direction of the turntable 2 and Si containing gas is impeded from entering from a downstream side relative to a rotation direction of the turntable 2. The separation gas is not limited to nitrogen (N₂) gas and may also be, for example, inert gas such as argon (Ar) gas.

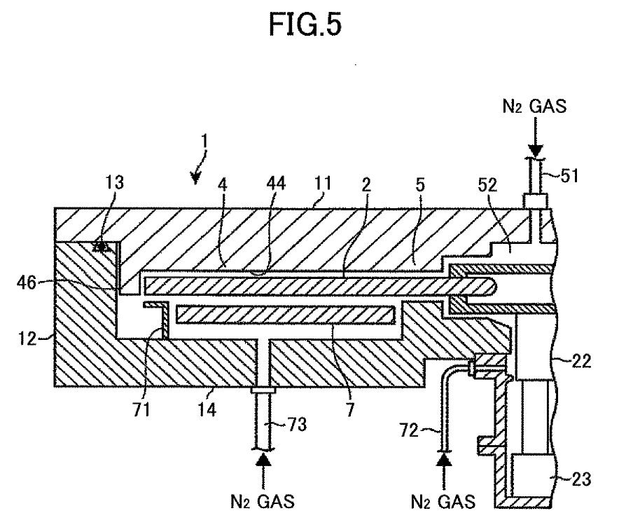

As shown in FIG. 5, a protrusion portion 5 is provided on a back surface of the ceiling plate 11 so that the inner circumference of the protrusion portion 5 faces the outer circumference of the core portion 21 that fixes the turntable 2. The protrusion portion 5 opposes the turntable 2 at an outer area of the core portion 21. In addition, the protrusion portion 5 is integrally formed with the convex portion 4 so that a back surface of the protrusion portion 5 is at the same height as that of a back surface of the convex portion 4 from the turntable 2. Additionally, FIGS. 2 and 3 show the inner configuration of the vacuum chamber 1 as if the vacuum chamber 1 is severed along a horizontal plane lower than the ceiling surface 45 and higher than the separation gas nozzles 41, 42.

As stated above, the back surface of the ceiling plate 11 of the vacuum chamber 1 (i.e. ceiling surface from a viewpoint of the wafer receiving area of the turntable 2 (concave portion 24)) includes the first ceiling surface 44 and the second ceiling surface 45 higher than the first ceiling surface 44 are arranged in the circumferential direction in the vacuum chamber 1. FIG. 1 is a cross-sectional view of the vacuum chamber 1 illustrating the higher ceiling surfaces 45. FIG. 5 is a cross-sectional view of the vacuum chamber 1 illustrating the low ceiling surface 44. As shown in FIGS. 2 and 5, at a circumferential portion (or at an outer side portion toward the inner circumferential surface of the vacuum chamber 1) of the sector-shaped convex portion 4, there is provided a bent portion 46 that bends in an L-shape and faces an outer end surface of the turntable 2. There are slight gaps between the outer circumferential surface of the bent portion 46 and the chamber body 12 turntable 2 because the convex portion 4 is attached on the back surface of the ceiling portion 11 and removable from the chamber body 12. The same as the convex portion 4, the bent portion 46 also prevents reaction gases from entering from both sides, so that both reaction gases are prevented from intermixing. The gap between the inner circumferential surface of the bent portion 46 and the outer end surface of the turntable 2 and the gap between the outer circumferential surface of the bent portion 46 and the chamber body 12 may be the same as the height of the ceiling surface 44 with respect to from the surface of the turntable 2.

In the separation area D, the chamber body 12 has an inner circumferential surface formed close to an outer circumferential surface of the bent portion 46 and formed on orthogonal planes as illustrated in FIG. 5. In areas besides the separation area D, the chamber body 12 is dented outward from a portion corresponding to the outer circumferential surface of the turntable 2 down through the bottom portion 14 of the chamber body 12 and has a rectangular shaped vertical cross-section, as shown in FIG. 1. An area of this dented area connected to the first process area P1 is referred to as a first evacuation area E1. An area of this dented area connected to the second process area P2 is referred to as a second evacuation area E2. As illustrated in FIGS. 1 and 3, a first evacuation port 61 is provided in the bottom portion below the evacuation area E1 and a second evacuation port 62 is provided in the bottom portion below the evacuation area E2. The first and the second evacuation ports 61, 62 are connected to an evacuation unit 64 including, for example, a vacuum pump 64 via corresponding evacuation pipes 63. In FIG. 1, reference numeral 65 indicates a pressure adjustment unit.

As shown in FIGS. 1 and 5, a heater unit 7 as a heating portion is provided in a space between the bottom portion 14 of the vacuum chamber 1 and the turntable 2, so that the wafers W placed on the turntable 2 can be heated through the turntable 2 at a temperature of, for example, 300° C. determined by a process recipe. In addition, a cover member 71 is provided beneath the turntable 2 and near the outer circumference of the turntable 2 in order to surround the heater unit 7, so that the atmosphere where the heater unit 7 is located is partitioned from the atmosphere beginning from the space above the turntable 2 to the evacuation areas E1, E2. The cover member 71 has an upper edge bent outward to form a flange-like shape. The cover member 71 is arranged so that a slight gap is maintained between the back surface of the turntable 2 and the bent flange portion in order to prevent gas from flowing inside the cover member 71.

In an area closer to the center than the space where the heater unit 7 is housed, the bottom portion 14 comes close to the center back surface of the turntable 2 and the core portion 21, leaving slight gaps between the bottom portion 14 and the turntable 2 and between the bottom portion 14 and the core portion 21. In addition, there is a small gap between the rotational shaft 22 and an inner surface of the center hole of the bottom portion 14 through which the rotation shaft 22 passes. This small gap is in gaseous communication with the case body 20. A purge gas supplying pipe 72 is connected to an upper portion of the case body 20 so that N₂ gas as a purge gas is supplied to the slight gaps, thereby purging the slight gaps. Moreover, plural purge gas supplying pipes 73 are connected at predetermined angular intervals to the bottom portion 14 of the chamber body 12 below the heater unit 7 in order to purge the space where the heater unit 7 is housed.

A separation gas supplying pipe 51 is connected to the top center portion of the ceiling plate of the vacuum chamber 1, so that N₂ gas can be supplied as a separation gas to a space 52 between the ceiling plate 11 and the core portion 21. The separation gas supplied to the space 52 flows through the thin gap 50 between the protrusion portion 5 and the turntable 2 and then along the top surface of the wafer receiving area of the turntable 2 toward the circumferential edge of the turntable 2. Because the space 52 and the gap 50 are filled with the separation gas, the reaction gases (Si containing gas and O₃ gas) cannot be mixed through the center portion of the turntable 2.

In addition, a transfer opening 15 is formed in a side wall of the vacuum chamber 1 as shown in FIGS. 2 and 3. Through the transfer opening 15, the wafer W is transferred into or out from the vacuum chamber 1 by an external transfer arm 10. The transfer opening 15 is provided with a gate valve (not shown) by which the transfer opening 15 is opened or closed. When the concave portion 24 of the turntable 2 is in alignment with the transfer opening 15 and the gate valve is opened, the wafer W is transferred into the vacuum chamber 1 and placed in the concave portion 24 as a wafer receiving portion of the turntable 2 from the transfer arm 10. In order to lower/raise the wafer W into/from the concave portion 24, there are provided elevation pins (not shown) that are raised or lowered through corresponding through-holes formed in the concave portion 24 of the turntable 2 by an elevation mechanism (not shown).

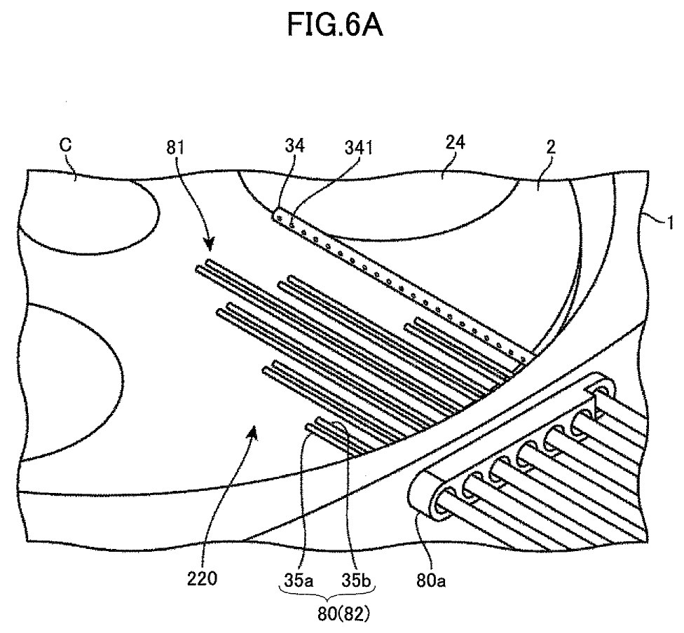

Next, the above-described activated gas injector 220 is described. The activated gas injector 220 is for reforming (performing property modification) a silicon oxide film (SiO₂ film) deposited on the wafer W by using plasma to cause a reaction between Si containing gas and O3 gas. As illustrated in FIGS. 6A and 6B, the activated gas injector 220 includes a gas guidance nozzle 34 (serving as a gas supply portion made of, for example, quartz) for supplying process gas into the vacuum chamber 1 for generating plasma, a plasma generating portion 80 being provided downstream of the gas guidance nozzle 34 relative to the rotation direction of the turntable 2 and including a pair of parallel sheath pipes 35a, 35b made of quartz for generating plasma from the process gas supplied from the gas guidance nozzle 34, and a cover body 221 (made of an insulator such as quartz) for covering the gas guidance nozzle 34 and the plasma generating portion 80 from above. Plural sets (e.g., 6 sets) of the plasma generating portion BO are provided. Incidentally, FIG. 6A illustrates a state where the cover body 221 is removed, and FIG. 6B illustrates a state where the cover body 221 is provided.

The gas introduction nozzle 34 and each of the plasma generating portions 80 are hermetically inserted into the vacuum chamber 1 in a direction from a base end portion 80a provided at an outer circumferential surface of the vacuum chamber 1 to a center portion of the turntable in a manner being parallel to the wafer W on the turntable 2 and being orthogonal relative to the rotation direction of the turntable 2. Further, each of the plasma generating portions 80 has different length extending from a top end part of the wafer W of the outer circumferential portion side of the turntable 2 to a distal end portion towards the center portion side of the turntable 2, so that the length of plasma generated in the radial direction of the turntable 2 can be changed in the plasma generating portion 80. In the order starting from the upstream side relative to the rotation direction of the turntable 2, the length R of each of the plasma generating portions 80 (more specifically, the length of the below-described electrodes 36a, 36b) may be, for example, 50 mm, 150 mm, 245 mm, 317 mm, 194 mm, and 97 mm. As described in the embodiments below, the length R of each of the plasma generating portions 80 (below described auxiliary plasma generating portion 82) may be changed according to, for example, a target recipe or the type of film to be deposited.

Here, the four sets of plasma generating portions 80 starting from the upstream side relative to the rotation direction of the turntable 2 are referred to as the main plasma generating portion 81. As described above, because the length R of the main plasma generating portion 81 is longer than the diameter of the wafer W (300 mm), the main plasma generating portion 81 is configured to generate plasma at a substrate receiving area between an inner edge of the turntable 2 and an outer edge of the turntable 2. Meanwhile, the other remaining five sets of plasma generating portions 80 besides those of the main plasma generating portions are referred to as auxiliary plasma generating portions 82. As described above, because the length R of the auxiliary plasma generating portion 82 is shorter than that of the main plasma generating portion 81, plasma either does not exist between the distal end portion of the auxiliary plasma generating portion 82 (center portion side of the turntable 2) and the center portion area C or only slightly diffuses from the outer circumference portion of the turntable 2. Therefore, as described below, each of the auxiliary plasma generating portions 82 is configured to compensate for the lack of plasma of the main plasma generating portion 81 at the outer circumferential portion of the turntable 2 and to make the concentration of plasma denser (more amount) at the outer circumferential portion of the turntable 2 than at the center portion of the turntable 2 at an area below the activated gas injector 220, so that the degree of reforming at the outer circumferential portion of the turntable 2 can be matched with the degree of reforming at the center portion of the turntable 2.

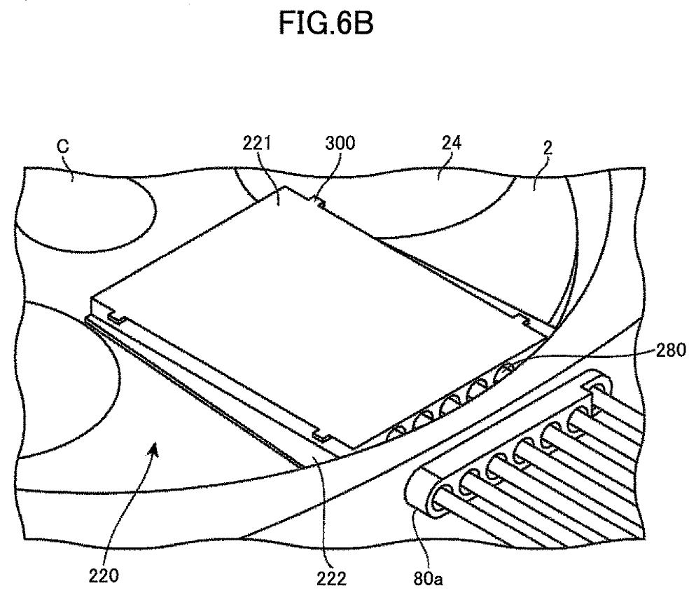

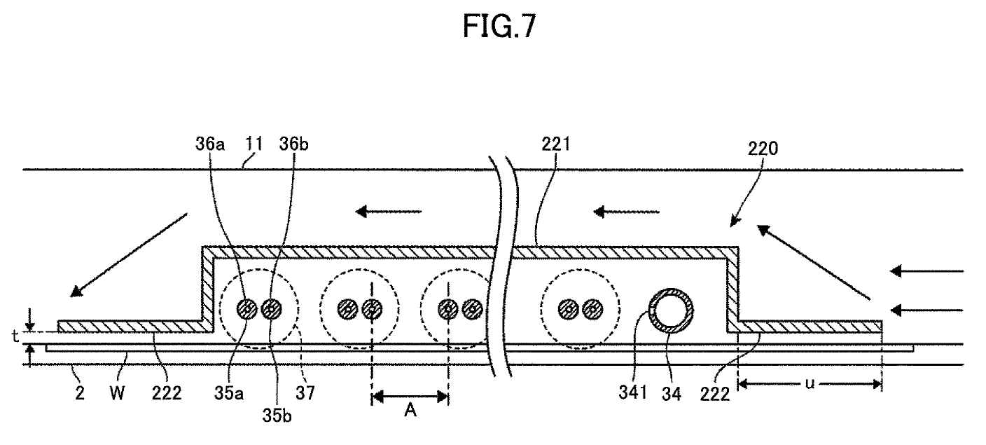

Each plasma generating portion 80 includes a set of sheath pipes 35a, 35b arranged close to each other. The sheath pipes 35a, 35b are formed of, for example, quartz, alumina (aluminum oxide), or yttria (yttrium oxide, Y₂O₃). As illustrated in FIG. 7, electrodes 36a, 36b formed of, for example, a nickel alloy or titanium are provided inside the sheath pipes 35a, 35b in a manner penetrating corresponding sheath pipes 35a, 35b. The electrodes 36a, 36b form parallel electrodes. As illustrated in FIG. 3, high frequency power at a frequency of, for example, 13.56 MHz is supplied at, for example, 500 W or less to the electrodes in parallel from a high frequency power source 224 via a matching box 225. The sheath pipes 35a, 35b are arranged so that the distance between the electrodes 36a, 36b penetrating the sheath pipes 35a, 35b is equal to or less than 10 mm (e.g., 4.0 mm). Incidentally, the sheath pipes 35a, 35b may be formed by, for example, applying yttria to a sheath pipe surface formed of quartz.

Further, the plasma generating portions 80 are hermetically attached to a sidewall of the vacuum chamber 1 with a base end portion 80a in a manner that the distance with respect to the wafer W on the turntable 2 can be adjusted. In FIG. 7, reference numeral 37 indicates a protection pipe connected a base end side of the sheath pipes 35a, 35b (inner wall side of the vacuum chamber 1). However, the protection pipe 37 is not illustrated in, for example, FIGS. 6A and 6B. Incidentally, the sheath pipes 35a, 35b are not illustrated in the drawings except for FIGS. 6A, 6B, and 7 for the sake of convenience.

As described with reference to FIG. 3, one end of a plasma gas introduction path 251 for supplying process gas for generating plasma is connected to a gas introduction nozzle 34. The other end of the plasma gas introduction path 251 breaks into two branches where one is connected to a plasma generation gas source 254 at which plasma generation gas (discharge gas) (e.g., argon (Ar) gas) is accumulated for generating plasma via a valve 252 and a flow rate adjustment portion 253 and the other is connected to an addition gas source 255 at which local discharge control gas (addition gas) (e.g., gas) is accumulated for controlling generation of plasma (chain) via the valve 252 and the flow rate adjustment portion 253. The addition gas has greater electron affinity than the discharge gas. Thereby, the discharge gas and the addition gas are supplied as process gas to the gas introduction nozzle 34. In FIG. 6A, reference numeral 341 indicates plural gas holes provided along a longitudinal direction of the gas introduction nozzle 34. Other than using Ar gas or O₂ gas as the process gas, helium (He) gas, H₂ gas, or an O containing gas, for example, may be used.

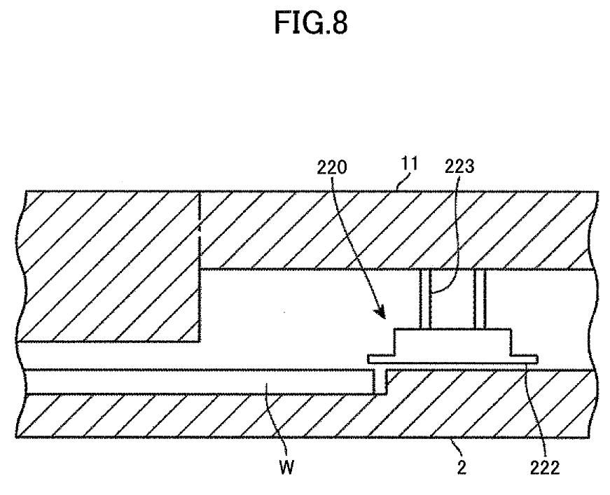

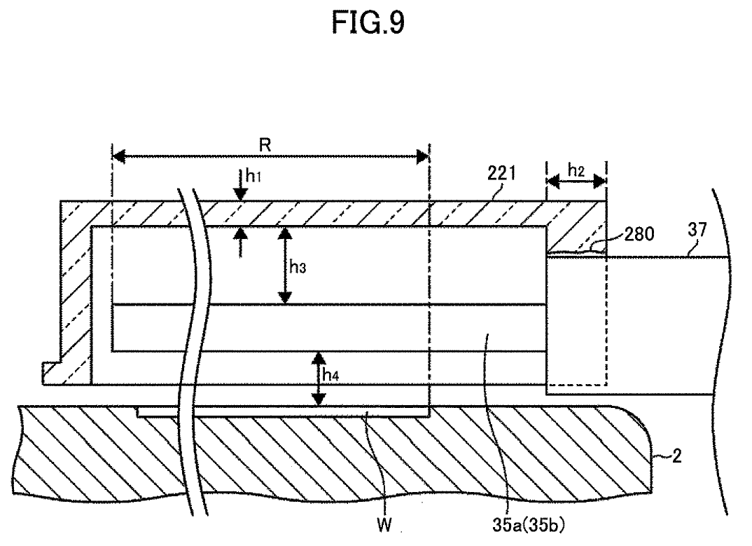

In FIG. 6B, reference numeral 221 indicates the above-described cover body. The cover body 221 is positioned covering an area at which the gas introduction nozzle 34 and the sheath pipes 35a, 35b are provided. The cover body 221 covers such area from the top side and from both sides (long side and short side). In FIG. 6B, reference numeral 222 indicates a gas flow control surface that horizontally extends in a flange-like manner from a bottom end portion of both sides of the cover body 221 to an outer side along a longitudinal direction of the activated gas injector 220. The gas flow control surface 222 is for preventing O₃ gas or N₂ gas from entering the cover body 221 from an upstream side of the turntable 2. Accordingly, the gas flow control surface 222 is formed in a manner that the gap between a bottom end plane of the gas flow control surface 222 and a top end plane of the turntable 2 becomes narrower and in a manner that the width u of the gas flow control surface 222 becomes greater the closer towards the outer circumferential side of the turntable 2. The flow of gas is greater at the outer circumferential side of the turntable 2 than that at the center portion of the turntable 2. Introduction ports 280 are formed in a sidewall surface of the cover body 221 at an outer circumferential side of the turntable 2. Each of the plasma generating portions 80 is attached to the sidewall surface of the vacuum chamber 1 in a manner having a corresponding protection pipe 37 at a base end side inserted through the introduction ports 280. A claw part 300 may be separately provided to each side surface at an upper end portion of the cover body 221 for supporting the cover body 221 by utilizing the ceiling plate 11. In FIG. 8, reference numeral 223 indicates a supporting member 223 provided at plural areas between the cover body 221 and the ceiling plate 11 of the vacuum chamber 1 for supporting the cover body 221 by using the claws 300. FIG. 8 schematically illustrates the position of the supporting member 223.

As illustrated in FIG. 7, the measurement t of the gap between the bottom end plane of the gas flow control surface 222 and the top plane of the turntable 2 is set to, for example, approximately 1 mm. The width u of one portion of the gas flow control surface 222 (for example, a portion of the gas flow control surface 222 facing an outer edge of the wafer W towards the rotation center of the turntable 2 when the wafer W is positioned below the cover body 221) may be 80 mm whereas the width u of another portion of the gas flow control surface 222 (for example, a portion of the gas flow control surface 222 facing an outer edge of the wafer W towards the inner sidewall of the vacuum chamber 1 when the wafer W is positioned below the cover body 221) may be 130 mm. Meanwhile, the space between the top end plane of the cover body 221 and the bottom plane of the ceiling plate 11 of the vacuum chamber 1 may be set to be equal to or more than 20 mm (e.g., 30 mm), so that the space is greater than the measurement t of the gap. Accordingly, the gases from the upstream side relative to the rotation direction of the turntable 2 (i.e. mixed gas of reaction gas and separation gas) flows between the cover body 221 and the ceiling plate 221.

In this example, regarding the positional relationship between the wafer W on the turntable 2 and the cover body 221, the thickness h1 of the top surface of the cover body 221 is 4 mm, the width h2 of the sidewall plane of the cover body 221 is 8 mm, the distance h3 between the top plane inside the cover body 221 and the electrode 36a (36b) is 9.5 mm, and the distance h4 between the electrode 36a (36b) and the wafer W on the turntable 2 is 7 mm. Further, in this example, the distance between the protection pipe 37 and the wafer W on the turntable 2 is 2 mm.

The film deposition apparatus 1000 includes a control portion 100 having a computer for controlling overall operation of the film deposition apparatus 1000. The control portion 100 has a memory in which a program(s) used for performing the below-described deposition process and the reforming process. The program(s) includes a group of steps for executing operations/processes performed by the film deposition apparatus 1000 and is installed from, for example, a hard disk, a compact disk, a magneto-optical disk, a memory card, or a flexible disk to the control part 100.

Next, a process carried out in the film deposition apparatus according to this embodiment is explained. First, a gate valve (not shown) is opened. Then, the wafer W is transferred into the vacuum chamber 1 through the transfer opening 15 by the transfer arm 10 and transferred to the concave portion 24 of the turntable 2. This wafer transferring is carried out by raising/lowering the elevation pins (not illustrated) from the bottom side of the vacuum chamber 1 via the through holes of the concave portion 24 when the concave portion 24 stops in a position in alignment with the transfer opening 15. Such wafer transferring is carried out by intermittently rotating the turntable 2, and five wafers are placed in the corresponding concave portions 24. Next, the gate valve is closed and the vacuum chamber 1 is evacuated to a predetermined pressure by the vacuum pump 64. Then, the wafers W are heated by the heater unit 7 at a temperature of, for example, 300° C. via the turntable 2 while rotating the turntable 2 in a clockwise direction and adjusting the inside of the vacuum chamber 1 to a predetermined processing pressure with a pressure adjusting portion 65. In addition, to ejecting Si containing gas and O₂ gas from the reaction gas nozzle 31, the reaction gas nozzle 32, respectively, Ar gas of 8 slm and O₂ gas of 2 slm are ejected from the gas introduction nozzle 34 so that the flow rate ratio is approximately 100:2-200:20. A high frequency power of 400 W at a frequency of 13.56 MHz is supplied in parallel between the sheath pipes 35a, 35b. Further, separation gas (N2 gas) of a predetermine flow rate is ejected from the separation gas nozzles 41, 42. N₂ gas of a predetermined flow rate is ejected from the separation gas supplying pipe 51 and the purge supplying pipes 71, 72.

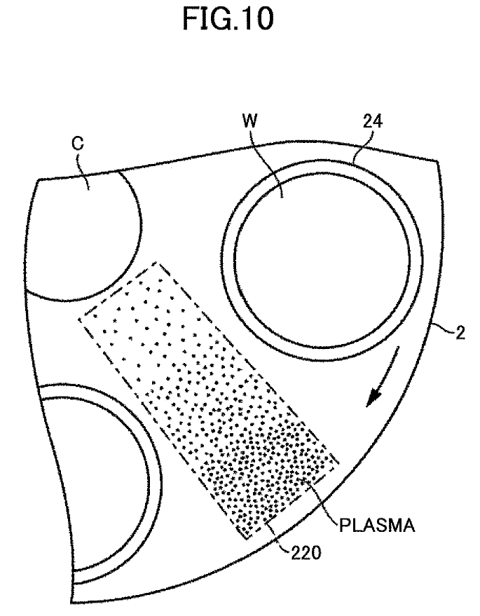

In this case, in the activated gas injector 220, the Ar gas and O₂ gas ejected from the gas introduction nozzle 34 to each sheath pipe 35a, 35b via gas holes 341 are activated by the high frequency power at the area in which the sheath pipes 35a, 35b are provided. For example, plasma such as Ar ions or Ar radicals are generated. As illustrated in FIG. 10, by adjusting the length R of the electrodes 36a, 36b extending from the base end portion side (side toward the outer circumferential portion of the turntable 2), the plasma (activated species) is generated so that the amount of plasma is more (higher concentration) at the outer circumferential portion side of the turntable 2 than at the center portion side of the turntable 2. The generated plasma descends towards the wafer W rotating together with the turntable 2 from the activated gas injector 220. In this case, although the rotation of the turntable 2 may make the plasma unsteady and may cause the plasma to be generated locally, the process gas being mixed with O₂ gas restrains the chain reaction of plasma of Ar gas and stabilizes the state of the plasma. It is to be noted that, although the length of plasma generated in each of the plasma generating portions 80 is different, the amount of plasma (density) generated in the plasma generating portion 80 is schematically illustrated in FIG. 10.

Meanwhile, by rotating the turntable 2, Si containing gas is adsorbed to the surface of the wafer W in the first process area P1 and then the Si containing gas adsorbed to the wafer W is oxidized. Thereby, one or more molecule layers of a silicon oxide film can be formed. Impurities such as moisture (OH group) and organic materials may be contained in the silicon oxide film due to residual radicals contained in the Si containing gas. When the wafer W reaches an area below the activated gas injector 220, a reforming process is performed on the silicon oxide film by using the above-described plasma. More specifically, for example, by bombarding Ar ions onto the surface of the wafer W, the above-described impurities are released from the silicon oxide film and chemical elements inside the silicon oxide film are rearranged, to thereby achieve consolidation (high densification) of the silicon oxide film. Accordingly, owing to the densification, the reformed Si oxide film becomes more resistant to wet-etching.

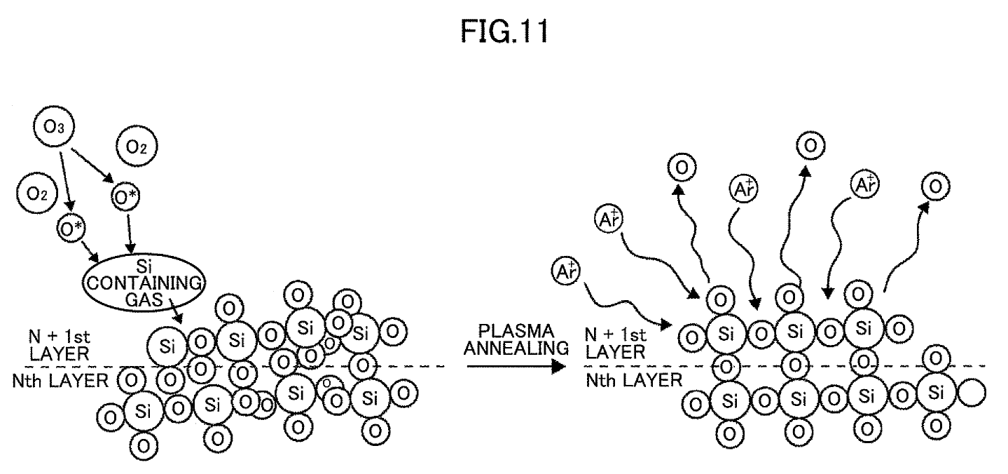

With the rotating turntable 2, a circumferential speed of the turntable 2 becomes greater in a position farther away from the center of the turntable 2 when the wafer W pass the area below the activated gas injector 220. Accordingly, the length of time of supplying plasma at the outer circumferential side of the turntable 2 is shorter than that at the center portion side of the turntable 2. Thus, the degree of reformation may decrease to approximately ⅓ with respect to center portion side of the turntable 2. However, as described above, each of the plasma generating portions 80 according to an embodiment of the present invention is configured to provide more plasma at the outer circumferential portion side of the turntable 2 than that at the center portion side of the turntable 2. Accordingly, the reforming process can be uniformly performed throughout (from the center portion side of the turntable 2 to the outer circumferential portion side of the turntable 2) the surface of the wafer W. Accordingly, the film thickness and the shrinkage amount of the silicon oxide film become uniform in the surface of the wafer W (in-plane direction of wafer W). Accordingly, by performing adsorption of Si containing gas, oxidation of Si containing gas, and reforming while rotating the turntable 2 in every deposition cycle, layers of the silicon oxide film can be sequentially formed. Thereby, the above-described rearrangement of elements occurs also among the reactive reaction products in the vertical direction (nth layer and (N+1) layer). Thus, as illustrated in FIG. 11, a layer(s) of a thin film can be formed having a uniform film thickness and a uniform film property with respect to the in-plane direction of the thin film (i.e. in the surface of each thin film) and the film thickness direction of the thin film (i.e. in-between layers of the thin film).

Although the separation area D is not formed between the activated gas injector 220 and the second reaction gas nozzle 32 in the vacuum container 1, O₃ gas and N₂ gas are guided from the upstream toward the activated gas injector 220 along with the rotation of the turntable 2. However, because the cover body 22 is formed covering each plasma generating portion 80 and the gas introduction nozzle 34, the upper area of the cover body 221 is wider than the lower area of the cover body 221 (gap t between the air flow control surface portion 222 and the turntable 2). Further, the pressure at the inner area of the cover body 221 is slightly more positive than the pressure at the outer area of the cover body 221 (inside the vacuum chamber 1) because process gas is supplied to the inner area of the cover body 221 from the gas introduction nozzle 34. Thus, it is difficult for gas flowing from the upstream side (relative to the rotation direction of the turntable 2) to enter the lower side of the cover body 221. Further, the gas flowing toward the activated gas injector 220 is guided to the upstream side by the rotation of the turntable 2. Therefore, although the flow of the gas becomes faster the more toward the outer circumference of the turntable 2, the gas can be prevented from entering the inside of the cover body 221 relative to the length direction of the activated gas injector 220 because the width u of the flow control surface 222 of the outer circumference side of the turntable 2 is greater than that of the inner circumference side of the turntable 2. Therefore, the gas flowing from the upstream side to the activated gas injector 220 flows to the evacuation port 62 of the downstream side via the upper area of the cover body 221 as described above with reference to FIG. 7. Therefore, because the O₃ gas and the N₂ gas are hardly affected by activation by high frequency, generation of, for example, NOₓ is controlled. Thus, the components that form the vacuum chamber 1 can be prevented from corroding. Further, the wafer W is also hardly affected by these gases. Incidentally, the impurities released from the silicon oxide film by the reforming process are discharged together with Ar gas and N₂ gas from the evacuation port 62 after forming the impurities into the gases.

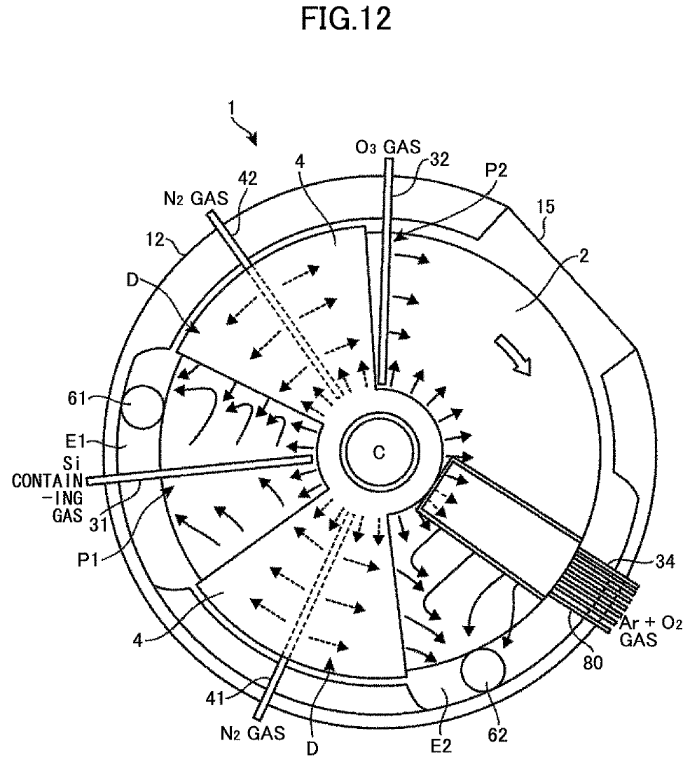

In this case, N₂ gas is supplied between the first process area P1 and the second process area P2. Further, N₂ gas (separation gas) is supplied to the center area C. Accordingly, Si containing gas and O₃ gas can be discharged without mixing with each other as illustrated in FIG. 12.

In this embodiment, because the inner circumferential surface of the chamber body 12 is dented (notched) and wide at the area below the second ceiling surface 45 (at which the first reaction gas nozzle 31, the second reaction gas nozzle 32, and the activated gas injector 220 are arranged), and because the first and second evacuation ports 61, 62 are positioned at the wide area, the pressure at the space below the second ceiling surface 45 is lower than the pressure at the narrow space below the first ceiling surface 44 and the pressure at the center area C. Incidentally, because N₂ gas is purged to the lower side of the turntable 2, there is neither a risk for the gas guided into the evacuation area E to pass below the turntable 2 nor is there a risk of, for example, Si containing gas or O₃ gas flowing into the gas supply area.

The parameters in this example are described as follows. In a case where the target substrate is a wafer W having a diameter of 300 mm, the rotation speed of the turntable 2 is, for example, 1 rpm-500 rpm. The process pressure is, for example, 1067 Pa (8 Torr). The flow rate of the Si containing gas is, for example, 100 sccm; the flow rate of the O₃ gas is, for example, 10000 sccm; the flow rate of the N₂ gas from the separation gas nozzles 41, 42 are, for example, 20000 sccm; and the flow rate of the N₂ gas from the separation gas supply pipe 51 at the center portion of the vacuum chamber 1 is, for example, 5000 sccm. Although the number of cycles of supplying reaction gas to a single wafer W (i.e. number of times the wafer W passes each of the process areas P1, P2) differs depending on the thickness desired, the number of cycles may be, for example, 1000 times.

With the above-described embodiment, in depositing a silicon oxide film by rotating the turntable 2 for enabling Si containing gas to be adsorbed to the wafer W and then supplying O₃ gas to the surface of the wafer W for causing reaction of the Si containing gas adsorbed on the surface of the wafer W, a reforming process is performed every cycle by supplying plasma of a process gas from the activated gas injector 220 to the silicon oxide film deposited on the wafer W. Accordingly, a thin film having satisfactory density with few impurities can be obtained. In the case of supplying plasma, the degree of reforming (plasma amount) the wafer W from the center portion side of the turntable 2 to the outer circumferential portion side of the turntable 2 can be adjusted in correspondence with the type of process by changing the length R of the plasma generating portion 80 (auxiliary plasma generating portion 82).

In a case where the degree (intensity) of reforming becomes larger at the center portion side of the turntable 2 than at the outer circumferential portion side of the turntable 2 due to the length of time of supplying plasma becoming longer at the center portion side of the turntable 2 than that at the outer circumferential portion side of the turntable 2 in correspondence with the rate of the wafer W passing the area below the activated gas injector 220, more plasma can be supplied at the outer circumferential side portion of the turntable 2 than at the center portion side of the turntable 2 by providing a main plasma generating portion 81 is provided together with an auxiliary plasma generating portion 82 that either prevents plasma generation at the center portion of the turntable 2 or reduces the generated (diffused) amount of plasma at the center portion of the turntable 2. Thereby, the reforming process can be performed for attaining a uniform film thickness and a uniform film property. Thus, as described in the experiments (examples) below, damaging of the wafer W due to excess or insufficient degree (intensity) of deforming performed on a portion(s) of the wafer W can be prevented. In a case where the degree (intensity) of deforming decreases from the center portion side of the turntable 2 to the outer circumferential portion side of the turntable 2, the degree (intensity) of deforming may become too strong at the center portion side of the turntable 2 when attempting to improve reforming performance at the outer circumferential portion side of the turntable 2. On the other hand, the degree (intensity) of deforming may become too weak (insufficient) at the outer circumferential portion side of the turntable 2 when attempting to improve reforming performance at the center portion side of the turntable 2. Therefore, such cases of attempting to improve reforming performance throughout the entire area (from the center portion side to the outer circumferential portion side) of the turntable 2, the range of parameters (e.g., process conditions) could become to narrow. However, according to an embodiment of the present invention, because the degree (intensity) of reforming is uniform in the radial direction of the turntable 2, a satisfactory reforming process can be performed throughout the entire surface (in-plane direction) of the wafer W. Therefore, with the film deposition apparatus 1000 according to an embodiment of the present invention, a wide range of parameters can be attained. Thus, the film deposition apparatus 1000 having a high degree of freedom can be obtained.

By arranging plural sets of plasma generating portions 80 for performing the reforming process, the energy required for reforming the silicon oxide film can be distributed (decentralized) to the plural plasma generating portions. Therefore, compared to a case of performing the reforming process by using a single set of plasma generating portions, the amount of plasma generated by a single plasma generating portion 80 can be reduced. Therefore, the deforming process is performed slow and gradually by forming moderate plasma in a wide area. Thus, damaging of the wafer W can be reduced. From another standpoint, in an case where, for example, moderate plasma conditions are set for performing a reforming process with a single set of plasma generating portions 80 and the reforming process is performed in a short time while rotating the turntable 2 at a low speed, it can be said that plasma can be supplied to a wide area while the turntable 2 is rotated at high speed. Therefore, the depositing process and the reforming process for a thin film can be performed in a short time while preventing the wafer W from being damaged by plasma and attaining satisfactory reforming performance.

By arranging plural plasma generating portions 80, degradation due to sputtering created by the plasma or the heat from each plasma generating portion 80 can be reduced because the amount of energy provided to a single plasma generating portion 80 is less compared to a case of arranging only a single set of plasma generating portions 80. Accordingly, impurities (quartz) generated by sputtering of, for example, the sheath pipes 35a, 35b can be prevented from being mixed into the wafer W.

Further, in performing a reforming process in each film deposition cycle inside the vacuum chamber 1, the reforming process is performed in the middle of passing the wafer W through the process areas P1, P2 in the circumferential direction of the turntable 2 so as not to interrupt the film deposition process. Therefore, the reforming process can be performed in a shorter amount of time compared to performing a reforming process after completing the film deposition process.

Further, because the cover body 221 prevents gas from the upstream side from flowing into the cover body 221, the gas can be prevented from affecting the deposition process. Thus, the reforming process can be performed in the middle of the film deposition process. Accordingly, there is no need to provide a separation area D dedicated for separating the gases from, for example, the second reaction gas nozzle 32 and the activated gas injector 220. Thus, the reforming process can be performed without increasing the cost of the film deposition apparatus 1000. Further, generation of a by-product gas (e.g., NOx) can be prevented. Accordingly, corrosion of components of the film deposition apparatus 1000 can be prevented. Further, because the cover body 221 is formed of an insulating material, plasma cannot be generated between the cover body 221 and the plasma generating portion 80. Therefore, the cover body 221 can be positioned close to the plasma generating portion 80. Thus, size reduction of the film deposition apparatus 1000 can be achieved.

Further, a chain of Ar gas plasma generation is prevented by supplying O₂ gas together with Ar gas. Accordingly, plasma can be prevented from being generated locally with respect to the longitudinal direction of the activated gas injector 220 throughout the reforming process (deposition process). Accordingly, the reforming process can be uniformly performed on the surface of the wafer W and as well as in between the surfaces of the wafer W. Further, because the electrodes 36a, 36b are positioned so that the distance between the electrodes 36a, 36b is short, a small output enables Ar gas to be activated (ionized) to a degree sufficient for performing a reforming process even in a case of a high pressure range (deposition pressure range) which is not optimum for ionizing the Ar gas.

Although the reforming process is performed each time of performing the film deposition process according to the above-described embodiment, there may also be a case where the reforming process is performed whenever the film deposition process is performed for a predetermined plural number of times (e.g., 20 times). When performing the reforming process in this case, Si containing gas, O₃ gas, and N₂ gas are stopped from being supplied, process gas is supplied from the gas introduction nozzle 34 to the activated gas injector 220, and high frequency power is supplied to the sheath pipes 35a, 35b. Further, the turntable 2 is rotated for, for example, 200 times for allowing 5 wafers W to sequentially pass the area below the activated gas injector 220. After performing the reforming process in such manner, the supplying of the Si containing gas, O₃ gas, and N₂ gas is resumed for performing the film deposition process. Accordingly, the reforming process and the film deposition process may be repetitively performed in such order. In this case also, a thin film having satisfactory density with few impurities can be obtained. In this case, there is no need to provide the cover body 221 as illustrated in FIG. 6A because the supplying of O₃ gas or N₂ gas is, stopped when performing the reforming process.

Further, in providing plural plasma generating portions 80, the above-described embodiment has one plasma generating portion 80 serving as the main plasma generating portion 81 and the remaining plasma generating portions 80 serving as auxiliary plasma generating portions 82 in which the auxiliary plasma generating portion 82 has a length R shorter than that of the main plasma generating portion 81. However, the length of the plasma generating portions 80 may be changed as shown in the below-described experiments (examples). For example, as illustrated in FIG. 13, all of the plasma generating portions 80 may have the same length and serve as the main plasma generating portion 81 (i.e. no auxiliary plasma generating portion 82). In a case of adjusting the amount of plasma so that the reforming process is performed at higher intensity at the center portion side of the turntable 2 than the outer circumferential portion side of the turntable 2, one end of the auxiliary plasma generating portion 82 may be horizontally extended from the center portion C to the outer circumferential portion of the turntable 2 whereas the other end of the auxiliary plasma generating portion 82 is bent upward (in a L-shape manner) and connected to the high frequency power source 224. Further, the auxiliary plasma generating portion 82 having such configuration may be arranged together with the auxiliary plasma generating portion 82 extending from the outer circumferential portion side of the turntable 2. Alternatively, the main plasma generating portion 81 may also be extended from the center portion C. Further, although the above-described embodiment has the plasma generating portions 80 extending between the center portion side and the outer circumferential side of the turntable 2 and perpendicularly intersecting the circumferential direction of the turntable 2, the plasma generating portion 80 may be configured having one end extending towards the center portion C from the inner wall of the vacuum chamber 1 in which the one end is bent towards an upstream side along a circumferential direction of the turntable 2 in an arcuate shape at a middle section relative to the radial direction of the turntable 2, so that a large amount of plasma could be generated at the middle section. Accordingly, the “rod-like” plasma generating portion 80 is not limited to a plasma generating portion 80 having a straight shape but may also be a plasma generating portion 80 having an arcuate or circular shape.

Although capacitive coupled plasma is generated using the above-described parallel electrodes 36a, 36b, capacitive coupled plasma may be generated by using coil type electrodes. In this case, as illustrated in FIG. 14, plural electrodes (antennas) 400 are provided in parallel in a manner extending straight (rod-like) towards the center portion side of the turntable 2 from the side surface of the vacuum chamber 1, being connected in a U-shape manner at the center portion side. In this case, the electrodes 400 may be formed having different lengths R. Further, in this case, three electrodes 400 are provided in a manner where the length of the electrodes 400 becomes shorter from the upstream side to the downstream side relative to the rotation direction of the turntable 2 (e.g., 310 mm, 220 mm, 170 mm, respectively). Reference numeral 401 in FIG. 14 indicates a common power source for generating capacitive coupled plasma connected to the electrodes 400 at both ends. In this case also, the amount of plasma can be adjusted in the radial direction of the turntable 2. Accordingly, the degree of reforming performed on the surface of the wafer W (i.e. in-plane direction of the wafer W) can be adjusted. Although the cover body 221 is provided in a manner covering the electrodes 400 and the gas introduction nozzle 34 in the embodiment of FIG. 14, the cover body 221 is not omitted in FIG. 14 for the sake of convenience.

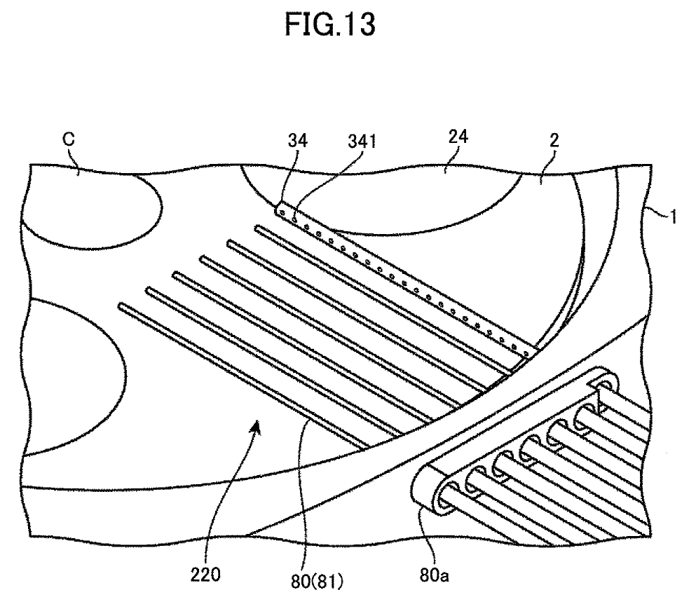

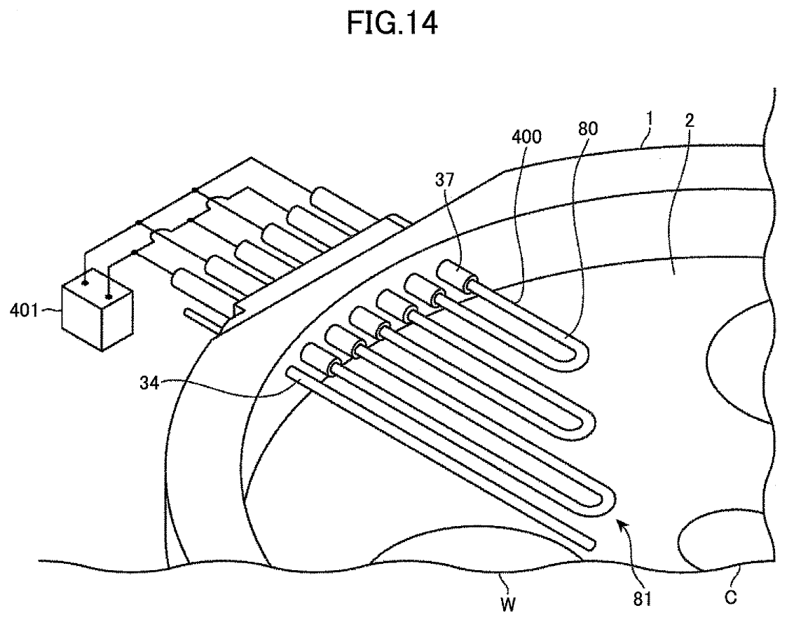

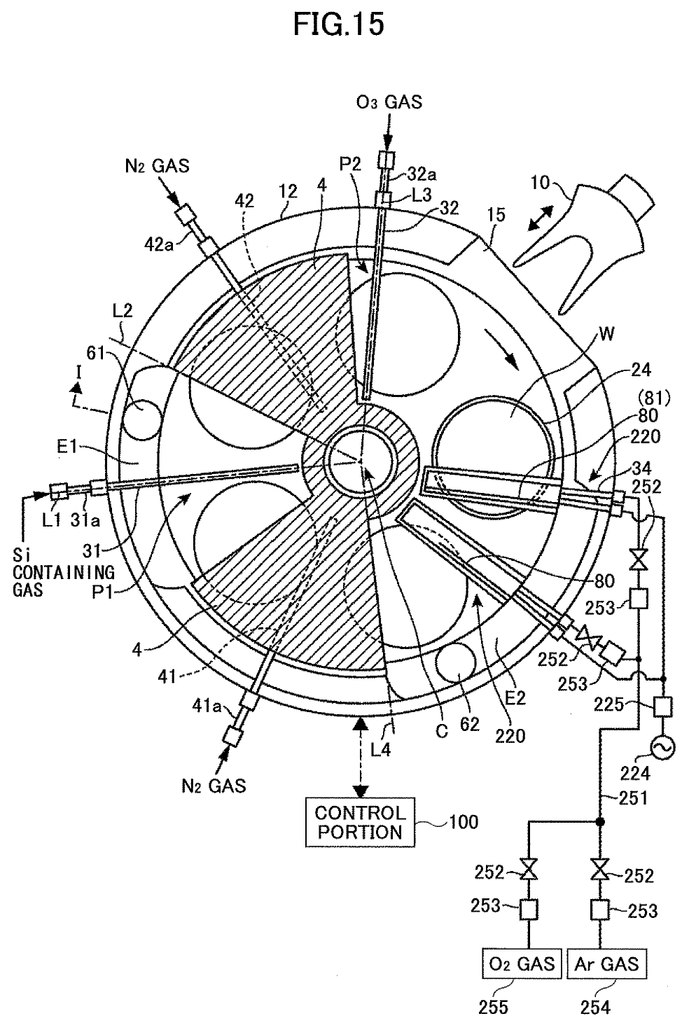

In providing plural plasma generating portions 80, the above-described embodiment has the plural plasma generating portions 80 provided in a manner housed in a single cover body 221 and sharing the same gas introduction nozzle 34, the gas introduction nozzle 34 may be provided in correspondence with each of the plural plasma generating portions 80. For example, as illustrated in FIG. 15, a plasma generating portion 80 may be provided to each set of the plasma generating portion 80 and the corresponding gas introduction nozzle 34. In the embodiment illustrated in FIG. 15, two plasma generating portions 80 are arranged, in which one of the plasma generating portions 80 is the main plasma generating portion 81 and the other plasma generating portion 80 is the auxiliary plasma generating portion 80.

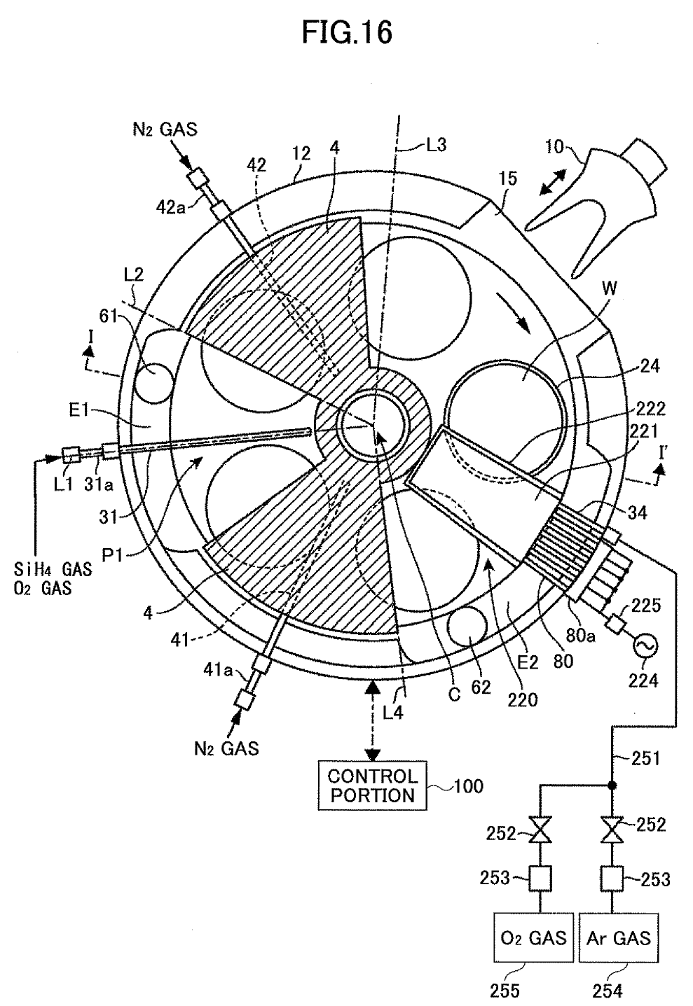

Although a film deposition method such as ALD or MLD is used by the film deposition apparatus 1000 according to the above-described embodiment of the present invention, the film deposition apparatus 1000 may form a thin film by using a CVD method by changing, for example, the film deposition temperature or the reaction gas. In this case, as illustrated in FIG. 16, a thin film formed of SiO₂ may be formed by using a mixed gas of two types (e.g., SiH₄ gas and O₂). Although both the film deposition process (e.g., CVD method or ALD method) and the reforming process are performed inside the vacuum chamber 1, the reforming process using the above-described activated gas injector 220 may be performed on a wafer having a film deposited thereon by another apparatus. In this case, instead of using the above-described film deposition apparatus 1000, a reforming apparatus 1000′ is used as another example of the plasma process apparatus. In a case of performing a reforming process on a thin film using the reforming apparatus 1000′, a wafer W having a thin film formed thereon (deposited wafer) is placed on the turntable 2 inside the vacuum chamber 1, then the turntable 2 is rotated, and then the vacuum chamber 1 is evacuated. Then, the plasma is generated and a reforming process is performed using the activated gas injector 220. By rotating the turntable 2, for example, a plural number of times, a uniform film thickness and a uniform film property can be attained in the surface of the thin film (in-plane direction). FIG. 17 is a schematic diagram illustrating the reforming apparatus 1000′ according to an embodiment of the present invention. However, the above-described transfer opening 15, for example, is omitted.

In providing plural plasma generating portions 80, the above-described embodiment has at least one plasma generating portion 80 serving as the main plasma generating portion 81 that generates plasma from the center portion side of the turntable 2 to the outer circumferential portion side of the turntable 2. However, in another embodiment of the present invention, plural (e.g., two) plasma generating portions 80 may be used as the main plasma generating portion 81. As illustrated in FIG. 18, one end of a first plasma generating portion 80 extends towards the outer circumferential side of the turntable 2 from the center portion C. Further, one end of a second plasma generating portion 80 (auxiliary plasma generating portion 82) is bent (e.g. bent in a L-shape) and connected to the high frequency power source 224 via the matching box 225. Further, in an area deviated from the first plasma generating portion 80 in an upstream side or a downstream side relative to the rotation direction of the turntable 2, the second plasma generating portion (auxiliary plasma generating portion 82) extends towards the center portion side from the outer circumferential side of the vacuum chamber 1 in a manner where the auxiliary plasma generating portion 82 (second plasma generating portion 80) and the one end of the first plasma generating portion 80 overlaps relative to the rotation direction of the turntable 2, to thereby enable plasma to be generated from the center portion side of the turntable 2 to the outer circumferential side of the turntable 2. Accordingly, in this embodiment, the main plasma generating portion 81 is formed by the first and second plasma generating portions 80. This embodiment can also achieve adjustment of the degree of reforming in the center portion and the outer circumferential portion of the turntable 2 and reduce damaging of the wafer W compared to a case of using a single plasma generating portion 80. Further, degrading (damage) of each plasma generating portion 80 can also be reduced.

As for the process gas for depositing the silicon oxide film, the first reaction gas may be, for example, bis(tertiary-butylamino) silane (BTBAS), dichlorosilane (DCS), hexachlorodisilane (HCD), tris(dimethyl amino) silane (3DMAS), monoamino-silane, or the like, Trimethyl Aluminum (TMA), tetrakis-ethyl-methyl-amino-zirconium (TEMAZ), tetrakis-ethyl-methyl-amino-hafnium (TEMAH), bis(tetra methyl heptandionate) strontium (Sr(THD)₂), (methyl-pentadionate)(bis-tetra-methyl-heptandionate) titanium (Ti(MPD)(THD)) or the like. By using the first reaction gas, an aluminum oxide film, a zirconium oxide film, a hafnium oxide film, a strontium oxide film, or a titanium oxide film may be deposited. As the second reaction gas that oxidizes the above-listed first reaction gases, water vapor or the like may be used. In a case of performing a process that does not use O₃ gas (e.g., a case of modifying, for example, a TiN film), NH3 gas or an N (nitrogen) containing gas may be used as the plasma generating process gas supplied from the gas introduction nozzle 34.

As for the order in which the plasma generating portions 80 are arranged, the plasma generating portions 80 may be arranged in a manner where the length of each of the plasma generating portions 80 increases from the upstream side to the downstream side relative to the rotation direction of the turntable 2. Alternatively, the plasma generating portions 80 may be arranged in a manner where the length of each of the plasma generating portions 80 decreases from the upstream side to the downstream side relative to the rotation direction of the turntable 2. The number of the plasma generating portions 80 may be two or more. The gas introduction nozzle 34 for supplying process gas to the activated gas injector 220 may be arranged on the downstream side relative to the plural plasma generating portions 80 because the pressure at the inner area of the cover body 221 is slightly more positive than the pressure at the outer area of the cover body 221. Alternatively, the gas introduction nozzle 34 may be formed of gas ejection holes provided at the ceiling surface of the cover body 221 or at the sidewall of the outer circumferential portion side of the turntable 2 for allowing process gas to be supplied from the gas ejection holes. Other than using the above-described rod-like electrodes 36a (400), a device capable of generating plasma by, for example, optical energy (e.g., laser) or thermal energy may be used.

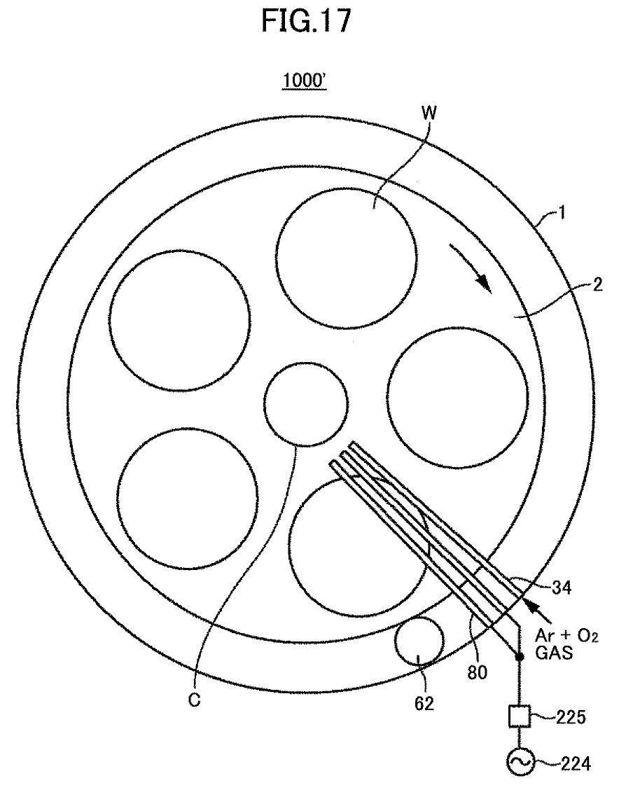

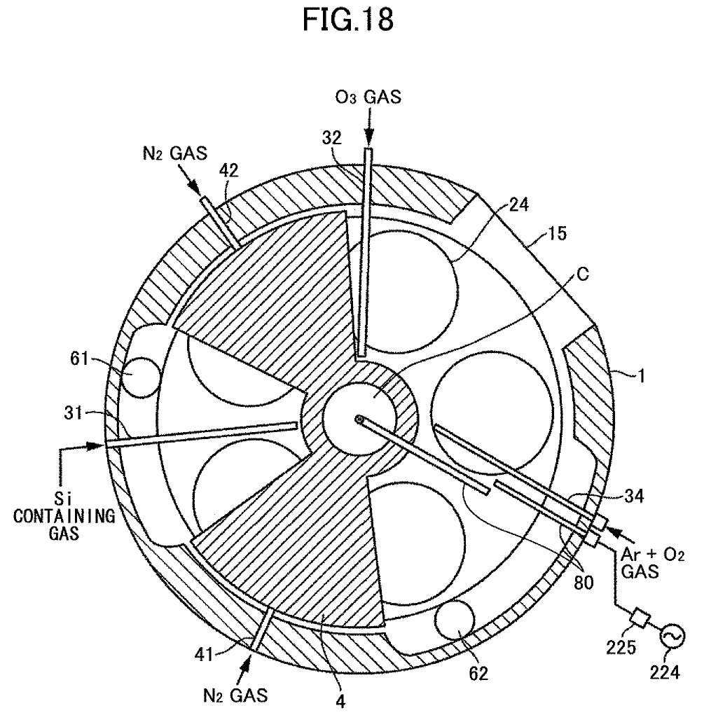

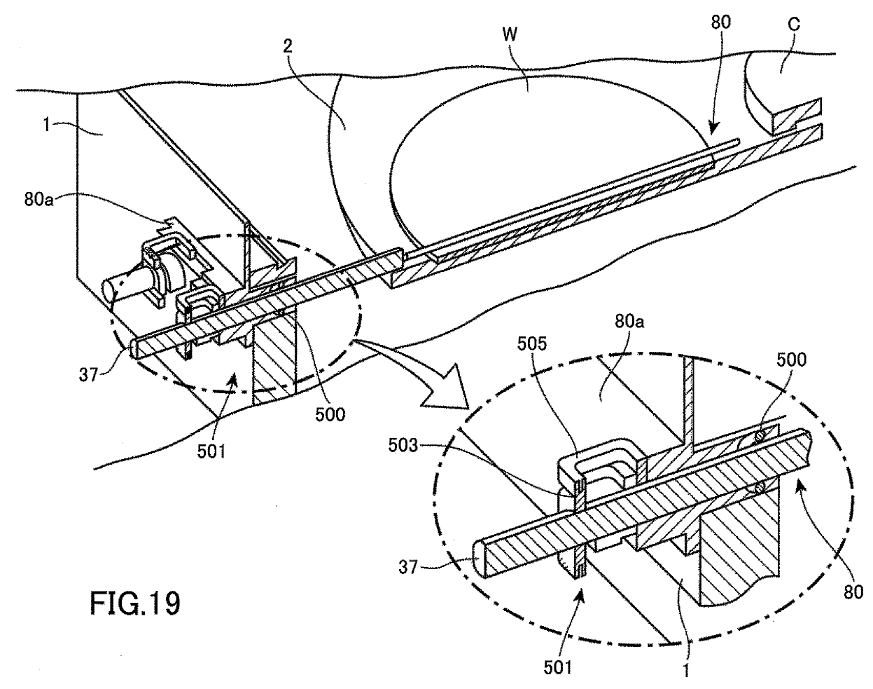

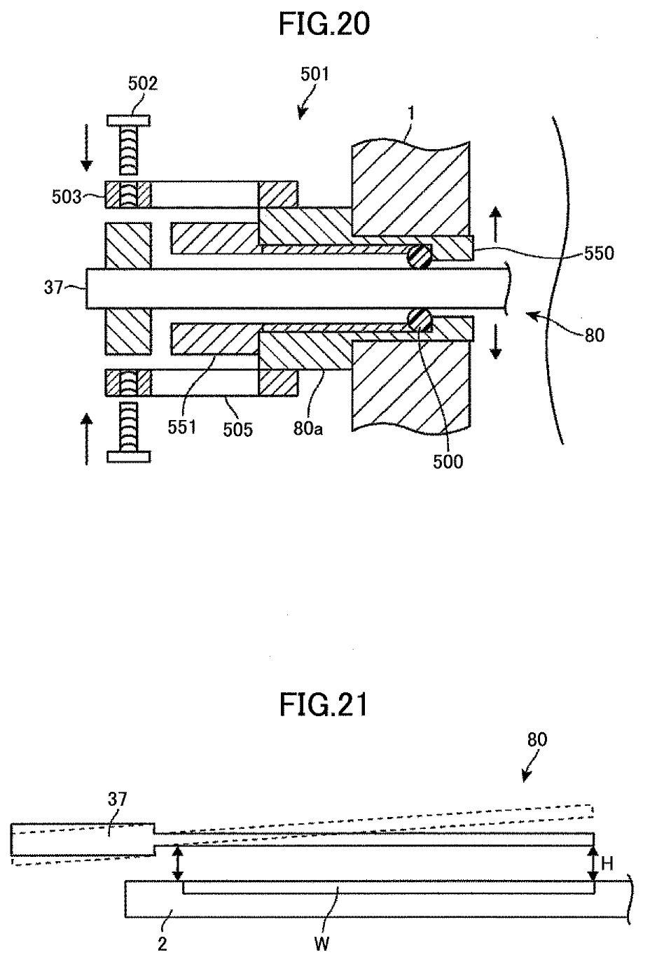

The plasma generating portion 80 may be inclined towards the longitudinal direction of the plasma generating portion 80 in the area between the center side portion and the outer circumferential side portion of the turntable 2. More specifically, as illustrated in FIGS. 19 and 20, each of the plasma generating portions 80 is inserted into the vacuum chamber 1 from a sidewall portion of the vacuum chamber 1. A first sleeve 550 is formed by penetrating a portion of the sidewall of the vacuum chamber 1 at which the plasma generating portion 80 (protection pipe 37) is inserted. The protection pipe 37 is inserted to the first sleeve 550. The first sleeve 550 has an inner circumferential surface of an end portion towards the inner area of the vacuum chamber 1 formed along the outer circumferential surface of the protection pipe 37 and has an inner circumferential surface of a base end portion towards outer area of the vacuum chamber 1 formed with an expanded diameter. Further, a sealing member (e.g., o-ring) 500 formed of resin or the like is provided in a manner surrounding the protection pipe 37 in a circumferential direction at an area between the expanded portion of the first sleeve 550 and the protection pipe 37. A ring-like second sleeve 551 is provided in the area between the first sleeve 550 and the protection pipe 37 in a manner that the second sleeve 551 is retractable from the outer side of the vacuum chamber 1 to the sealing member 500. By applying pressing force from the second sleeve 551 to the sealing member 500 in the direction of the vacuum chamber 1, the sealing member 500 hermetically seals the protection pipe 37 with respect to the vacuum chamber 1. Accordingly, the protection pipe 37 (plasma generating portion 80) using the sealing member 500 as a base point, is supported in a manner that the end portion towards the vacuum chamber 1 can freely move (elevate). In FIG. 19, the first and second sleeves 550, 551 are not shown.

The plasma generating portion 80 includes an inclination adjustment mechanism 500 provided at the outer side of the vacuum chamber 1. The inclination adjustment mechanism 501 raises and lowers the base end portion of the protection pipe 37 extending from the second sleeve 551 towards the outer side of the vacuum chamber 1. The inclination adjustment mechanism 501 includes first and second main body portions 505 provided in a manner extending along the longitudinal direction of the protection pipe 37 at two areas below and above the protection pipe 37, respectively. Each of the first and second main body portions 505 includes a fastening portion 503 having one end fixed to one of the first and second main body portions 505 or the outer wall of the vacuum chamber 1 and the other end penetrating one of the first and second main body portions 505. By fastening a screw portion 502 to the fastening portion 503 of one of the first and second main body portions 505 from an upper side or a lower side, the plasma generating portion 80 can be fixed to the vacuum chamber 1 having the base end portion of the protection pipe 37 maintaining a raised or lowered state.

Further, as illustrated in FIG. 21, by raising and elevating the base end of the protection pipe 37 with the inclination adjustment mechanism 501, the end portion of the plasma generating portion 80 can be raised and lowered inside the vacuum chamber 1 (in which the fulcrum is the portion where the protection pipe 37 is supported by the sealing member 500) while the sealing member 500 maintains the inner area of the vacuum chamber 1 in a hermetically sealed state. In this embodiment of the present invention, the distance H between the top surface of the wafer W on the turntable 2 and the bottom edge of the plasma generating portion 80 is set to 9 mm at the outer circumferential side of the turntable 2 whereas the distance H between the top surface of the wafer W on the turntable 2 and the bottom edge of the plasma generating portion 80 at the inner portion side of the turntable 2 can be adjusted between 8-12 mm. FIG. 21 is a schematic diagram of the plasma generating portion 80 according to an embodiment of the present invention.

Accordingly, by having the plasma generating portion 80 inclined in the longitudinal direction of the plasma generating portion 80, the distance H between the wafer W and the plasma generating portion 80 can be adjusted relative to the radial direction of the turntable 2. Therefore, as described in the below-described experiments (examples), the degree of reforming (amount of plasma) can be adjusted relative to the radial direction of the turntable 2. That is, because the degree of vacuum inside the vacuum chamber 1 is low in the above-described pressure range of the inside of the vacuum chamber (equal to or more than 66.66 Pa (0.5 Torr), activated species (e.g., ions and radicals) inside the plasma is easily inactivated (inert). Therefore, the amount of plasma (concentration) that reaches the wafer W on the turntable 2 becomes less as the distance H between the plasma generating portion 80 and the wafer W becomes longer. Therefore, by inclining the plasma generating portion 80, the amount of activated species reaching the wafer W relative to the rotation direction of the turntable 2 can be adjusted.

Accordingly, in a case where, for example, the degree of reforming at the center portion side of the turntable 2 is larger than that at the outer circumferential side portion of the turntable 2, the end portion of the plasma generating portion 80 and the wafer W on the turntable 2 can be separated from each other by raising the end portion of the plasma generating portion 80. Thereby, the degree of reforming at the center portion side of the turntable 2 can be matched with the degree of reforming at the outer circumferential side portion of the turntable 2. In a case where, for example, the degree of reforming at the center portion side of the turntable 2 is less than that at the outer circumferential side portion of the turntable 2, the end portion of the plasma generating portion 80 and the wafer W on the turntable 2 can be positioned closer to each other by lowering the end portion of the plasma generating portion 80. In this case, the degree of reforming can be matched more accurately in the radial direction of the turntable 2 by adjusting the angle of inclination of the plasma generating portion 80 with the inclination adjustment mechanism 501 together with adjusting the length(s) R of the plural plasma generating portions 80.

The inclination adjustment mechanism 501 may be provided in each of the plasma generating portions 80. Alternatively, the inclination adjustment mechanism 501 may be provided in one or more of the plasma generating portions 80. Although the inclination adjustment mechanism 501 is positioned towards the outer side of the vacuum chamber 1 in the above-described embodiment, the inclination adjustment mechanism 501 may be positioned at an inner area of the vacuum chamber 1. Thereby, the bottom end portion of the protection pipe 37 extending from the inner circumferential surface of the vacuum chamber 1 to the center portion C is supported in a manner that the bottom end portion of the protection pipe 37 can be freely raised and lowered. FIG. 19 illustrates a portion of the vacuum chamber 1 in an enlarged state for a described one of six plasma generating portions according to an embodiment of the present invention.

As shown in FIG. 7, the distance A between facing electrodes 36a, 36b of two plasma generating portions 80 arranged adjacent to each other along the rotation direction of the turntable 2 is preferred to be sufficiently long for preventing discharge between the adjacent plasma generating portions 80. A preferred range of the distance A may differ depending on the high frequency power supplied from the high frequency power supply 224 to the plasma generating portions. For example, in a case where two plasma generating portions are provided and a value of the high frequency power supplied from the high frequency power source 224 is 800 W, the preferred distance A is equal to or more than 45 mm, and more specifically, approximately 80 mm or more.

Further, the above embodiment describes a case of providing 6 plasma generating portions 80 (see FIG. 6A) along with adjusting the length(s) R of the plasma generating portions 80 (auxiliary plasma generating portions 82) for adjusting the degree of reforming in the radial direction of the turntable 2 with the activated gas injector 220. Alternatively, as illustrated in FIG. 22, the lengths R of all of the plasma generating portions 80 may be adjusted to equal length along with providing a diffusion restraining plate (diffusion restraining portion) 510 to each of the plasma generating portions 80 for preventing diffusion of the plasma applied from the plasma generating portion 80 to the wafer W.

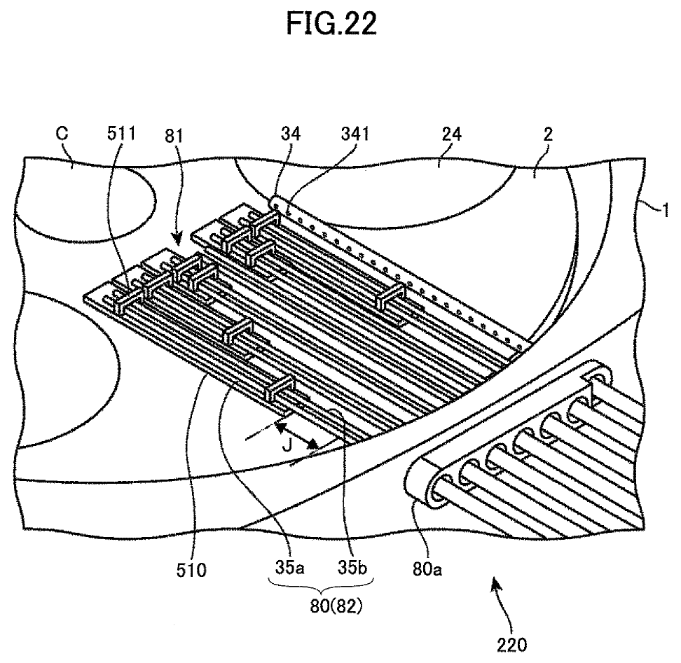

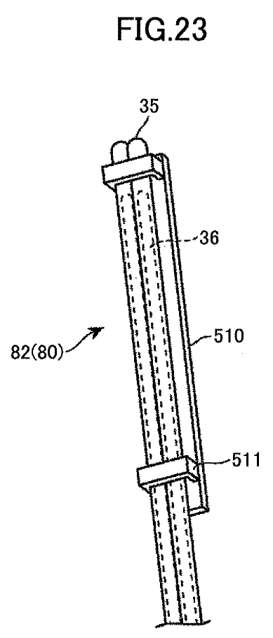

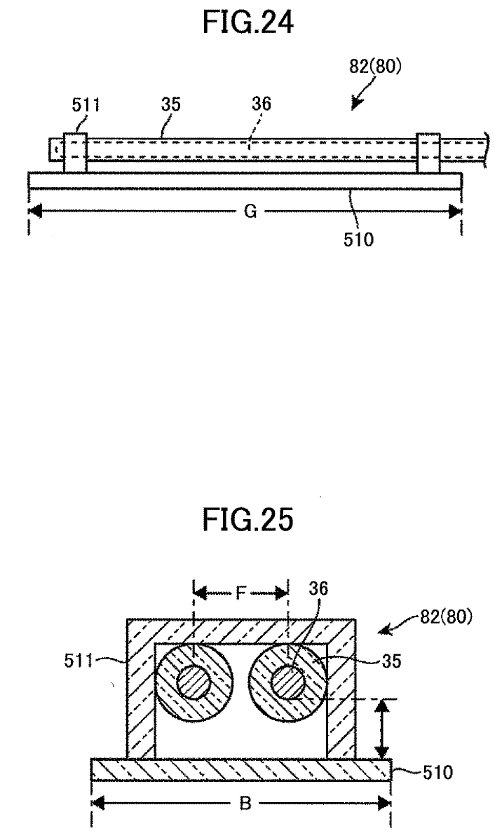

As illustrated in FIGS. 23-25, the diffusion restraining plate 510 is a plate-like insulating material (e.g., quartz) horizontally extending in a longitudinal direction of the auxiliary plasma generating portion 82. The diffusion restraining plate 510 serves to prevent plasma (activated species such as radicals and ions) from diffusing towards the wafer W side. The diffusion restraining plate 510 are provided at an end portion side (side towards the center portion of the turntable 2) of each of the auxiliary plasma generating portions 82 in a manner facing downward below the corresponding auxiliary plasma generating portion 82. Further, the diffusion restraining plate 510 extends from, for example, a position approximately 5 mm closer towards the center portion of the turntable 2 than the end portion of the auxiliary plasma generating portion 82 to a base end portion of the auxiliary plasma generating portion 82. The length G (measured from the center portion side of the turntable 2) of each of the diffusion restraining plates 510 arranged from the upstream side to the downstream side relative to the rotation direction of the turntable 2 is 220 mm, 120 mm, 120 mm, 220 mm, and 270 mm, respectively. Therefore, in a case where the letter J in FIG. 22 indicates a valid length of the auxiliary plasma generating portion 82 (i.e. the length from a position above the end portion (toward the outer circumferential side of the turntable 2) of the wafer W to a position above the end portion of the diffusion restraining plate 510), the valid length of the auxiliary plasma generating portion 82 is equal to the length R of the auxiliary plasma generating portions 82 illustrated in FIG. 6A. Accordingly, in this embodiment also, each of the auxiliary plasma generating portions 82 serves to compensate insufficient plasma of the main plasma generating portion 81 at the outer circumferential portion of the turntable 2, so that the plasma concentration (amount of plasma) at the outer circumferential side portion side of the turntable is more than the plasma concentration (amount of plasma) at the center portion side of the turntable 2.

Each of the diffusion restraining plates 510 is hung at plural parts (e.g., two parts) of the sheath pipes 35a, 35b in the longitudinal direction of the plasma generating portion 80 by fixing members 511 as illustrated in FIG. 23. Each of the fixing members 511 is formed of an insulating member such as quartz. Each of the fixing members 511 is connected to a corresponding diffusion restraining plate 510 by extending upward from both end portions (relative to the rotation direction of the turntable 2) of the diffusion restraining plate 510 and horizontally bending in a manner covering the sheath pipes 35a, 35b. In this embodiment, the width B of the diffusion restraining plate 510 relative to the rotation direction of the turntable 2 is, for example, approximately 70 mm. In FIG. 25, the letter F indicates the distance between the center lines of the electrodes 36a, 36b of each of the plasma generating portions 80. In this embodiment, the distance F is 10 mm or less (e.g., 7 mm). Incidentally, the cover body 221 is omitted from FIGS. 23-25.

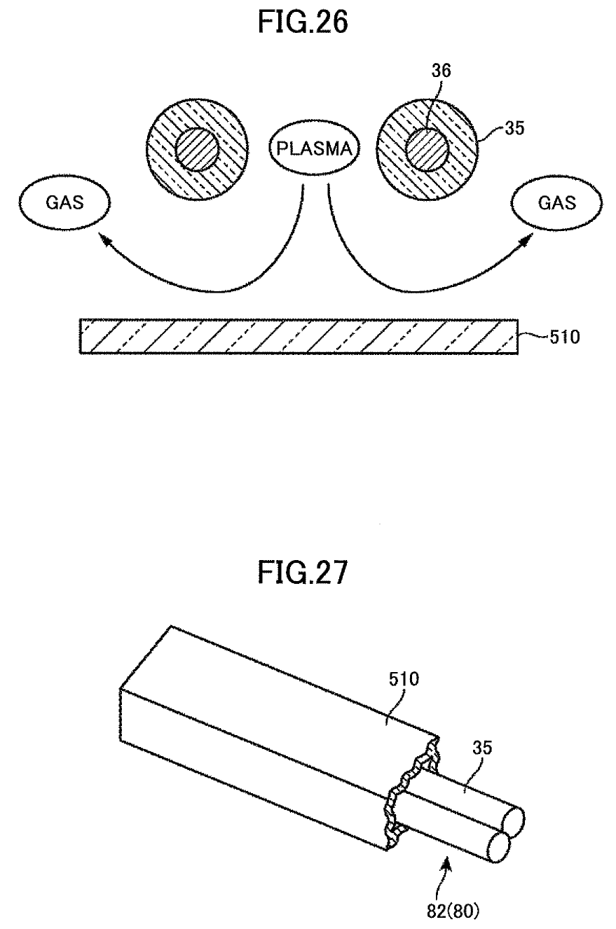

By providing the diffusion restraining plates 510 along with the auxiliary plasma generating portions 82, the amount of plasma supplied to the wafer W at the area of the center portion side of the turntable 2 becomes less than the amount of plasma supplied to the wafer at the circumferential edge portion of the turntable 2. That is, as illustrated in FIG. 26, in a case where plasma (ions and radicals) of a process gas is generated between the electrodes 36a and 36b, the plasma descends towards the wafer W moved to a position below the auxiliary plasma generating portion 82. However, because the diffusion restraining plate 510 is provided between the auxiliary plasma generating portion 82 and the wafer W on the turntable 2, the plasma is restrained from diffusing towards the turntable 2 side by the diffusion restraining plate 510. Thereby, the plasma diffuses in a horizontal direction along the upper surface of the diffusion restraining plate 510 (towards the upstream and downstream sides relative to the rotation direction of the turntable 2, the center portion side and the outer circumferential portion side of the turntable 2). As described above, because the activated species inside the plasma are easily inactivated, a portion of the plasma restrained from descending towards the turntable 2 becomes inactive (inert) as the plasma diffuses in the horizontal direction. Accordingly, even in a case where the inactivated plasma (gas) contacts the wafer W, the degree of reforming is reduced compared to an activated plasma not restrained by the diffusion restraining plate 510. Therefore, the degree of deforming is less in the area below the diffusion restraining plate 510 compared to that in the area toward the base end portion having no diffusion restraining plate 510 provided thereto. As illustrated in the below-described experiments (examples), because radicals inside the plasma have longer life-span compared to ions inside the plasma (more difficult to inactivate), radicals may roundabout the diffusion restraining plate 510 and reach the wafer W in an activated state. However, even in such a case, the diffusion restraining plate 510 can prevent reforming by the ions inside the plasma.

By providing the diffusion restraining plate 510, the same effects as the above-described gas injector 220 illustrated in FIGS. 6A-6B can be attained. Further, by forming the plasma generating portions 80 with equal length R, the high frequency power supplied to each of the plasma generating portions 80 can be uniform. That is, in a case of supplying the same amount of power from high frequency power source 224 to the plasma generating portions 80 where the lengths R of the plasma generating portions are different, a larger amount of power is supplied to the plasma generating portions 80 having long length than the plasma generating portions 80 having short length due to the different electrostatic capacity values of the plasma generating portions 80. Accordingly, in a case where the main plasma generating portion 81 is provided in a manner extending from an inner edge of a receiving area of the wafer W (end portion towards the center portion side of the turntable 2) to an outer edge of a receiving area of the wafer W (outer circumferential portion side of the turntable 2), the auxiliary plasma generating portion 81, which is shorter than the main plasma generating portion 81, generates weaker plasma (less plasma concentration) than that of the main plasma generating portion 81. Accordingly, in order to appropriately compensate for the lack of plasma at the outer edge of the receiving area of the wafer W, it may be difficult to adjust the value of the power supplied from the high frequency power source 224. Therefore, it is advantageous to form the auxiliary plasma generating portion 82 with a short length in a case of forming the main plasma generating portions 81 with equal length and adjusting the positions of the diffusion restraining plates 510.

That is, in the case of forming the plasma generating portion 80 with equal length and using the diffusion restraining plates 510 as illustrated in FIG. 22, the high frequency power supplied to the plasma generating portions 80 can be made to be uniform by adjusting by the amount of plasma supplied to each auxiliary plasma generating portion 82 in the radial direction of the turntable 2 and adjusting the valid length J of each auxiliary plasma generating portion 82. Accordingly, the amount of plasma supplied from each of the plasma generating portions 80 in the radial direction of the turntable 2 can be easily adjusted. Further, because the plasma generating portion 80 having the same length R can be used for both the main plasma generating portion 81 and the auxiliary plasma generating portion 82, the adjustment of the length R can be performed by simply replacing the diffusion restraining plate 510. Further, using the plasma generating portion 80 having the same length R for both the main plasma generating portion 81 and the auxiliary plasma generating portion 82 is cost effective.

Further, in another case, the above-described inclination adjustment mechanism 501 may be used together with the diffusion restraining plates 510. In this case, in addition to performing “digital” adjustment of the amount of plasma with the diffusion restraining plates 510, “analog” adjustment of the amount of plasma is performed by using the inclination adjustment mechanism 501. Thereby, the amount of plasma (degree of reforming) in the radial direction of the turntable 2 can be adjusted in a wider range.

Although the above-described embodiments of FIGS. 22-26 have the diffusion restraining plates 510 provided below the plasma generating portions 50, another embodiment may use a box-like diffusion restraining plate 510 covering the surrounding of plasma generating portion 80 (i.e. lower surface, both side surfaces, upper surface, and end portion of the plasma generating portion 80). In providing the diffusion restraining plate 510 inside the vacuum chamber 1, the diffusion restraining plate 510 may be hung from the ceiling plate 11 of the vacuum chamber 1 or fixed to an inner wall of the vacuum chamber 1. As a material of the diffusion restraining plate 510 other than quartz, the diffusion restraining plate 510 may be formed with, for example, an insulating member formed of alumina (Al₂O₃).

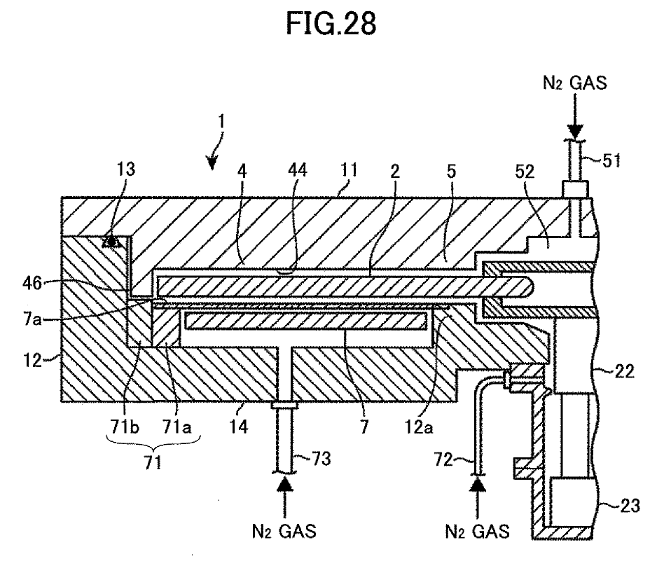

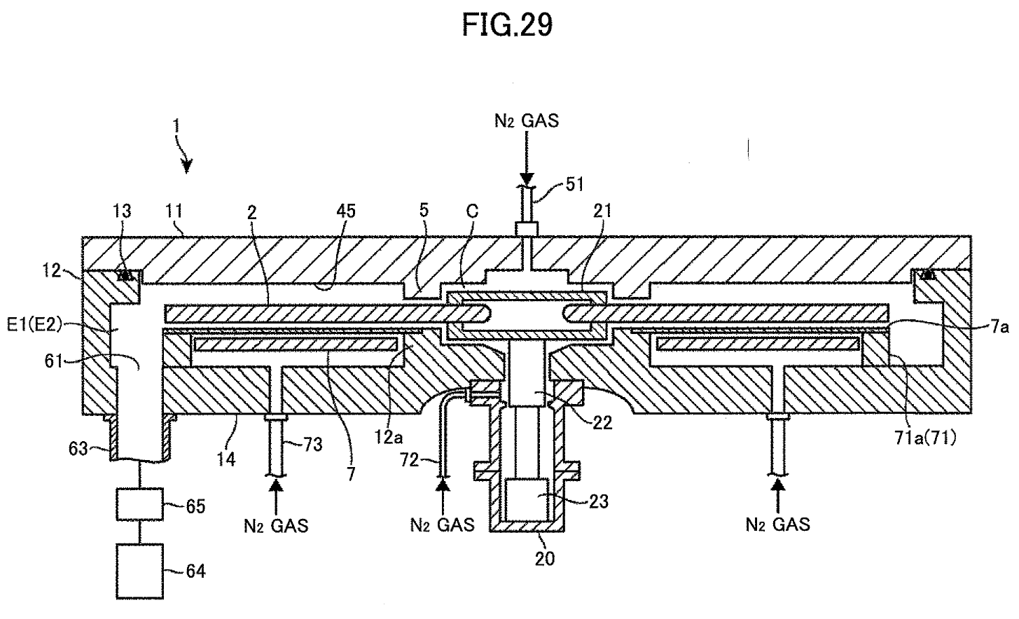

In another embodiment, the cover member 71 provided at the periphery of the heater unit 7 may be configured as illustrated in FIGS. 28 and 29. That is, the cover member 71 may include inner members 71a facing upward to the outer edge portion of the turntable 2 and outer members 71b provided between the inner member 71a and the inners surface of the vacuum chamber 1. The outer members 71b are dented in, for example, an arcuate shape above the evacuation ports 61, 62 for providing the evacuation areas E1, E2 for enabling air communication between the evacuation ports 61, 62 and an area above the turntable 2. In the area below the bent portion 46, an upper end surface of the outer member 71b is provided in the vicinity of the bent portion 46. In order to prevent gas from entering the area where the heater unit 7 is provided, a cover part 7a formed of, for example, quartz is provided between the heater unit 7 and the turntable 2 from an inner circumferential wall of the outer member 71b to an upper end portion of a protruding part 12a at the bottom of the vacuum chamber 1.

### EXAMPLES

Next, examples for testing the effects attained by embodiments of the present invention are described.

### First Example

How the degree of reforming changes in the radial direction of the turntable was tested by comparing a case of providing a single plasma generating portion 80 in the above-described film deposition apparatus 1000 with a case of providing plural plasma generating portions (in this example, 6) 80 in the above-described film deposition apparatus 1000. In the case of providing 6 plasma generating portions 80, a case where all of the 6 plasma generating portions 80 are formed having an equal length R of 300 mm and a case where the 6 plasma generating portions 80 are formed having different lengths R of 50 mm, 150 mm, 245 mm, 317 mm, 194 mm, and 97 mm from the upstream side relative to the rotation direction of the turntable 2, respectively. In evaluating the degree of reforming, a silicon oxide film of 150 nm was deposited on the wafer W beforehand without using the activated gas injector 220, then the reforming process was performed on the wafer W, then the difference of film thickness before and after the reforming process was calculated, and then the shrinkage rates (=(film thickness before the reforming process−film thickness after the reforming process)÷film thickness before the reforming process×100)) at plural areas of the wafer W in the radial direction of the turntable 2 was obtained. The reforming process was performed under the following conditions.

### (Reforming Conditions)

Process gas: He (helium) gas/O₂ gas=2.7/0.31/minute
Processing pressure: 533 Pa (4 Torr)
High frequency power: 400 W
Rotations of turntable 2: 30 rpm
Processing time: 5 minutes

### (Test Results)

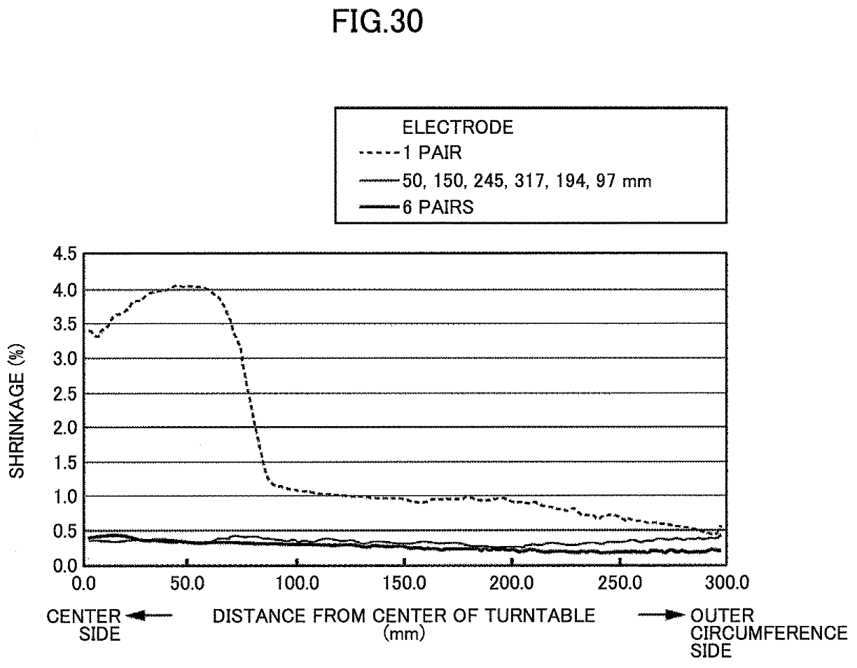

As illustrated in FIG. 30, in the case of providing a single plasma generating portion 80, the reforming process was intense at the center portion side of the turntable 2 and became less intense toward the outer circumferential side portion of the turntable 2. Therefore, in a case of attempting to perform a satisfactory reforming process on the outer circumferential side portion of the turntable 2 by using a single plasma generating portion 80, the reforming process becomes too intense at the center portion side of the turntable 2. Thereby, the wafer W is likely to be damaged. On the other hand, in the case of providing 6 plasma generating portions 80, the reforming process is uniformly performed from the center portion side of the turntable 2 to the outer circumferential side of the turntable 2. This is because the energy required for reforming the silicon oxide film is dispersed. Further, by changing the lengths of the plasma generating portions 80, it was found that the degree of reforming in the radial direction of the turntable 2 can be adjusted.

### Second Example

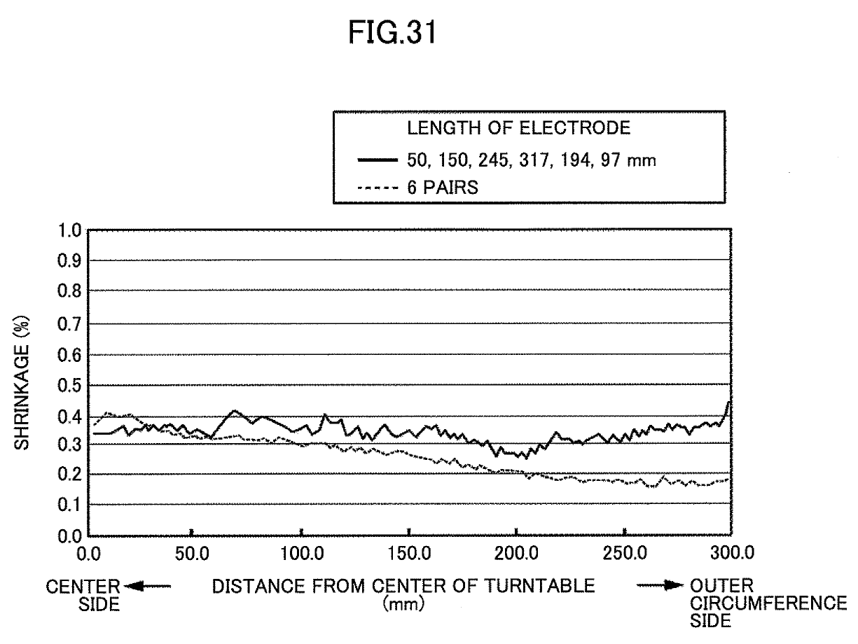

Next, the reforming process, being performed on a silicon oxide film under the same conditions as the first example, was evaluated. As illustrated in FIG. 31, it was found that the degree of reforming in the radial direction of the turntable 2 can be adjusted by changing the length of each of the plasma generating portions 80. In this example, a better uniformity can be attained by changing the length R of each of the plasma generating portions 80 than for the case of providing plasma generating portions 80 having equal length R.

### Third Example

Next, testing and evaluation were performed using plasma generating portions 80 of various lengths as illustrated in the following table.

TABLE

| | | EXAMPLE | EXAMPLE | EXAMPLE | EXAMPLE | EXAMPLE | EXAMPLE |
|---|---|---|---|---|---|---|---|
| | | 3-1 | 3-2 | 3-3 | 3-4 | 3-5 | 3-6 |
| ELECTRODE | | 300 | 50 | 50 | 50 | 85 | 97 |
| LENGTH | | 300 | 150 | 150 | 150 | 150 | 194 |
| (mm) | | 300 | 245 | 245 | 317 | 317 | 317 |
| | | 300 | 317 | 317 | 317 | 317 | 245 |
| | | 300 | 194 | 194 | 194 | 194 | 150 |
| | | 300 | 97 | 120 | 120 | 120 | 50 |
| THICKNESS | AVERAGE | 0.34 | 0.56 | 0.45 | 0.40 | 0.39 | 0.46 |
| DIFFERENCE | (nm) | | | | | | |
| | MAXIMUM | 0.53 | 0.69 | 0.55 | 0.52 | 0.54 | 0.58 |
| | (nm) | | | | | | |
| | MINIMUM | 0.22 | 0.46 | 0.32 | 0.28 | 0.26 | 0.26 |
| | (nm) | | | | | | |
| | RANGE | 0.31 | 0.23 | 0.23 | 0.24 | 0.28 | 0.32 |
| | (nm) | | | | | | |
| | UNIFORMITY | 45.43 | 20.53 | 25.64 | 30.25 | 35.71 | 35.02 |
| | (± %) | | | | | | |
| | VARIABILITY | 81.11 | 21.31 | 27.50 | 35.06 | 35.49 | 40.30 |
| | (%) | | | | | | |

The results show that the amount of plasma from the center portion side of the turntable 2 to the outer circumferential side of the turntable 2 can be adjusted by adjusting the length of each of the plasma generating portions 80. Thus, it was found that the reforming process can reduce the unevenness of, for example, film thickness. The table shows the results of film thicknesses obtained from various areas in the radial direction of the turntable 2 before and after performing the reforming process. Further, the table shows the lengths of the plasma generating portions 80 (electrodes) in correspondence with the order of the plasma generating portions 80 arranged from the upstream side of the turntable 2 to the downstream side of the turntable 2. Incidentally, “variability” in the table indicates the value of dividing three times the standard deviation with the population mean value.

### Fourth Example

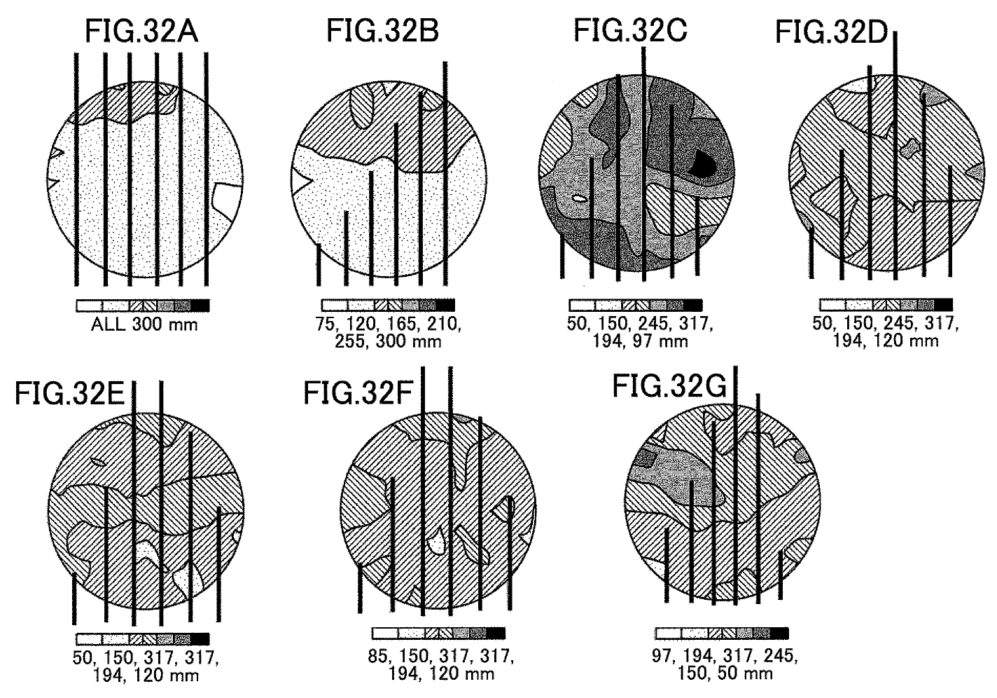

Next, the distribution of shrinkage rate of film thickness of the wafer W (in-plane direction) where the length of each of the plasma generating portions 80 are changed (as described in the third example) was measured. The results are illustrated in FIGS. 32A-32G. Incidentally, FIGS. 32A-32G also schematically illustrate the arrangement of each of the plasma generating portions 80 and the length of each of the plasma generating portions 80.

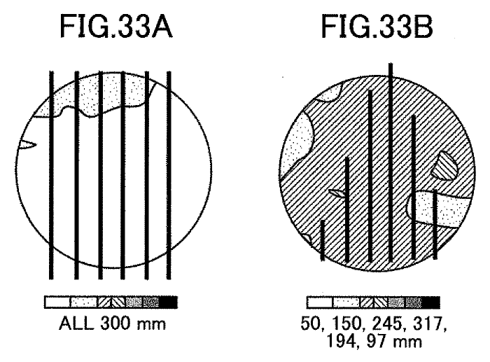

As illustrated in FIGS. 32A-32G, the shrinkage rate of film thickness in the in-plane direction changes by adjusting the length R of the plasma generating portions 80. Therefore, it is considered that the amount of plasma relative to the radial direction of the turntable 2 can also be changed by adjusting the length R of each of the plasma generating portions 80. In a case of setting the length of each of the plasma generating portions 80 to 50 mm, 150 mm, 245 mm, 317 mm, 194 mm, and 97 and in a case of setting the length of each of the plasma generating portions 80 to 97 mm, 194 mm, 317 mm, 245 mm, 150 mm, and 50 mm (i.e. changing the order of the arrangement of the plasma generating portions 80), it was found that there is hardly any difference of uniformity. FIGS. 33A and 33B show results obtained by changing the gradation (tone) of the shrinkage rate of the film thickness in a case of using the plasma generating portions 80 formed with the same length of 300 mm and in a case of using 6 plasma generating portions 80 formed with different length of 50 mm, 150 mm, 245 mm, 317 mm, 194 mm, and 97 mm from the upstream side of the turntable 2 to the downstream side of the turntable 2, respectively.

### Fifth Example

Next, damage of the wafer W caused by plasma was evaluated. The wafers W used in the evaluation were test wafers W having plural test chips including an antenna part with a surface of a phosphor-doped polycrystalline silicon film. Plasma was irradiated to the test wafers under the following conditions. Then, damage of each of the test chips (area of the antenna part before irradiating plasma÷valid antenna area after irradiating plasma) was evaluated. Incidentally, N₂ gas was used instead of using film deposition gas so as to prevent the damage layer formed on the test wafers W from being covered by a silicon oxide film.

### (Plasma Irradiation Conditions)

Process gas: Ar gas/O₂ gas=0.1 slm
Processing pressure: 533 Pa (4 Torr)
High frequency power: 400 W (13.56 Mz)
Rotation of turntable 2: 240 rpm
Processing time: 10 minutes
Deposition temperature: 350° C.
Gas for film deposition: N₂ gas/O₃ gas=200 sccm/6 slm Number of plasma generating portions: 6 plasma generating portions (length R: 50 mm, 150 mm, 245 mm, 317 mm, 194 mm, 97 mm), and 1 plasma generating portion (length R: 300 mm)
Plasma irradiation width: approximately 2 cm (passing plasma area of 2 cm for each of the plasma generating portions 80 per rotation of the turntable 2)

### (Examination Results)

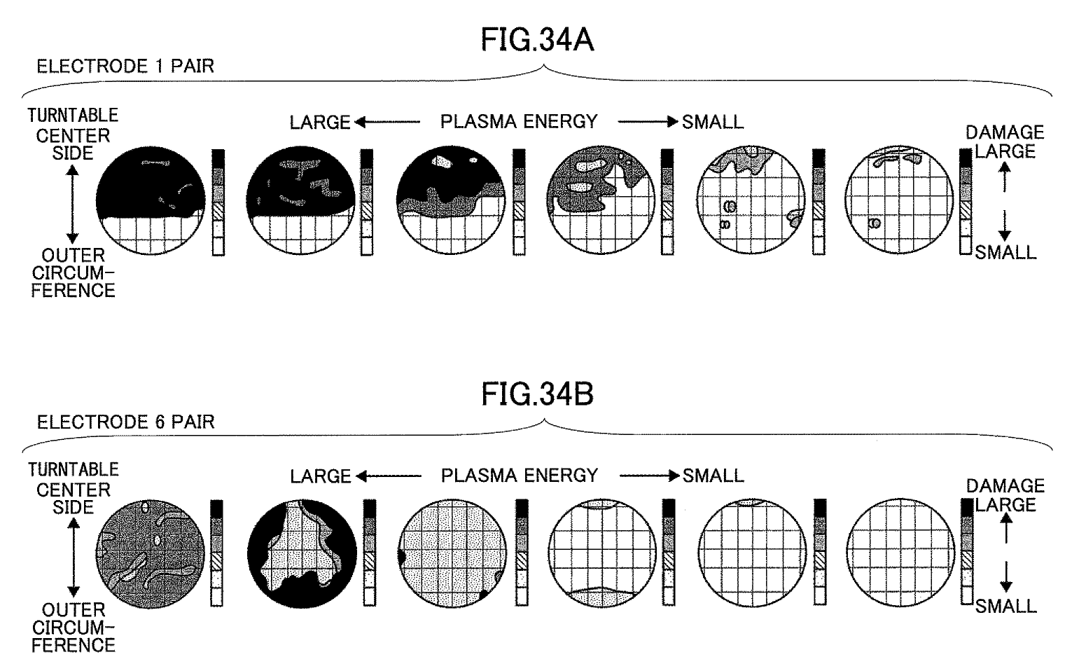

As illustrated in FIGS. 34A and 34B, damage becomes larger the closer towards the center portion side of the turntable 2 from the outer circumferential side portion of the turntable 2 in a case of using a single plasma generating portion 80. This tendency increased as the energy of plasma applied to the wafer W was increased. On the other hand, in a case of using 6 plasma generating portions 80, inconsistency of damage in the radial direction of the turntable 2 was hardly found. Further, there was no difference even where the energy of plasma applied to the wafer W was increased.

Accordingly, inconsistency in the degree of reforming occurs in the radial direction of the turntable 2 in the case of using a single plasma generating portion 80. In the case of using a single plasma generating portion 80, the selectable range of parameters (e.g., energy of plasma) is limited when attempting to uniformly perform the reforming process throughout the surface of the wafer W. On the other hand, it was found that inconsistency of the degree of reforming in the radial direction of the turntable 2 is reduced in the case of using 6 plasma generating portions 80. Further, the selectable range of parameters is wide in the case of using 6 plasma generating portions 80. FIGS. 34A and 34B schematically illustrate the above-described test chips in a lattice-like manner.

### Sixth Example

How the above-described cover body 221 prevents gas from entering the cover body 221 was simulated under the following conditions.

### (Simulation Conditions)

Process gas: Ar gas=20 slm
Processing pressure: 533 Pa (4 Torr)
High frequency power: 400 W (13.56 Mz)
Rotation of turntable 2: 30 rpm
Processing time: 10 minutes
Deposition temperature: 450° C.
Gas for film deposition: Si containing gas/O₃ gas=300 sccm/10 slm (200 g/Nm³)
Separation gas supplied to separation area D: N₂=20 slm
Separation gas supplied from above the center portion C: 3 slm
Separation gas supplied from below the center portion C and from the purge gas supplying pipe 73: 10 slm

### (Simulation Results)

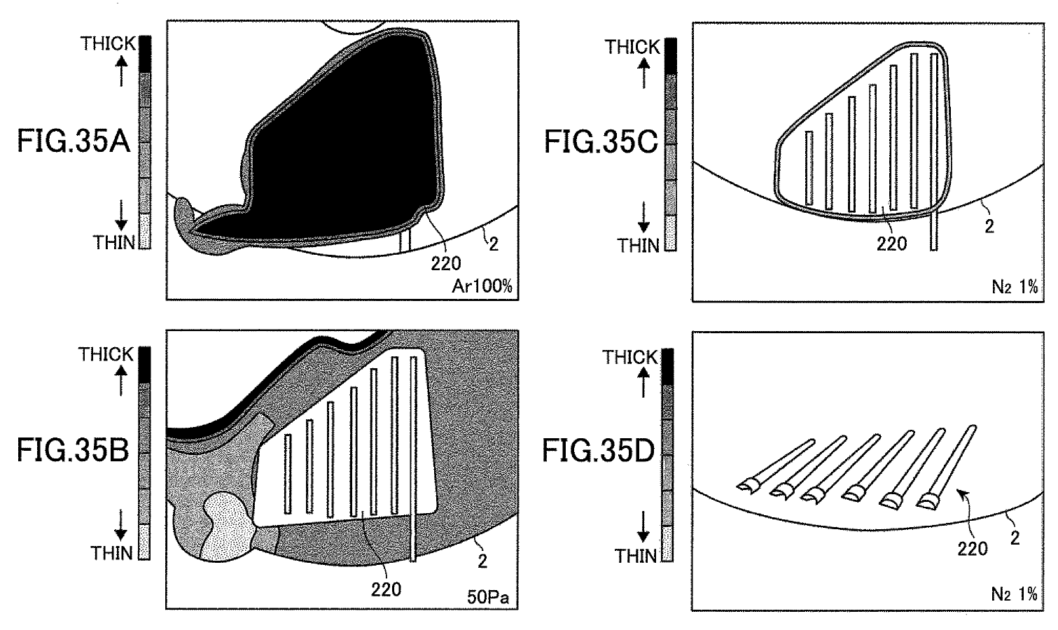

As illustrated in FIGS. 35A and 35B, it was found that Ar gas supplied from the gas introduction nozzle 34 is uniformly dispersed inside the cover member 221. Further, as illustrated in FIGS. 35C and 35C, it was found that the N₂ gas flowing towards the cover body 221 from the upstream side of the turntable 2 can be prevented from entering the cover body 221. Therefore, as described above, the O₃ gas ejected from the nozzles 32, 34 and the N₂ gas supplied to, for example, the separation area D are prevented from intermixing inside the cover body 221 and NOx is prevented from being generated in the cover body 221.

### Seventh Example

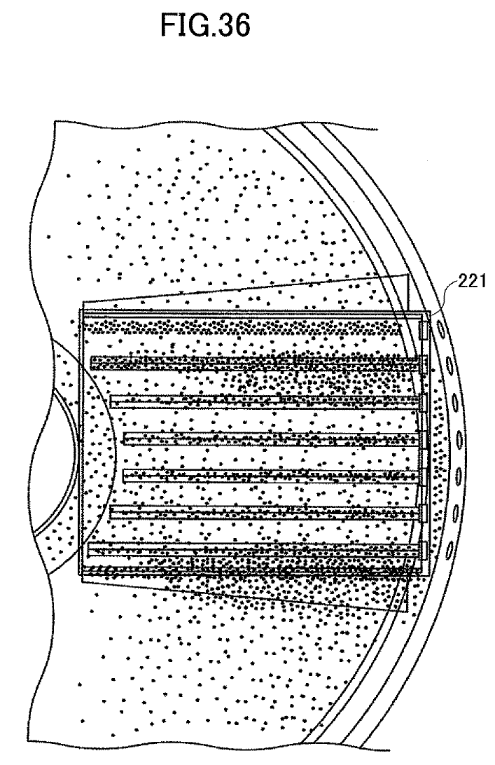

The distribution and flow rate of the process gas (He gas) inside the cover body 221 was simulated under the conditions where the processing pressure was 533 Pa (4 Torr) and the flow rate of the process gas was 3 slm. As illustrated in FIG. 36, it was found that the process gas is uniformly distributed inside the cover body 221 and that no disturbance occurs locally inside the cover body 221.

### Eighth Example

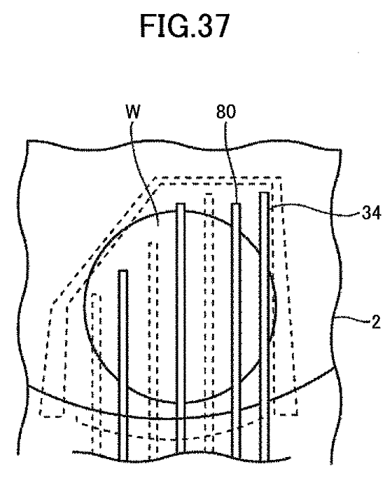

Next, evaluation of the property of the thin film obtained was performed in a case where the height of the distal end portion of the plasma generating portion 80 was adjusted with the above-described inclination adjustment mechanism 501. As illustrated in FIG. 37, the evaluation was performed in a case where the reforming process was performed using 3 plasma generating portions 80 in which the plasma generation portions 80 were positioned in the first position, the third position, and the fifth position from the upstream side of the turntable 2 among the 6 positions at which the above-described 6 plasma generating portions 80 are provided. Further, film thickness was measured under the conditions where the height (distance H) of the distal end portion of the plasma generating portion 80 at the third position was set to 8 mm, 10 mm, 11 mm, and 12 mm.

In this case, the height H of the distal end portion of the plasma generating portion 80 positioned at the first position and the fifth position are 17.5 mm and 16.5 mm, respectively. The distance between the wafer W situated towards the base end side (towards the side wall of the vacuum chamber 1) of the plasma generating portion 80 and the distal end portion of the plasma generating portion 80 positioned at the first position and the fifth position are both 9 mm. Although not illustrated, the sidewall of the vacuum chamber 1 at the second, fourth, and sixth positions (from the upstream side of the turntable 2) where no plasma generating portions are hermetically sealed. The film deposition conditions and the reforming conditions of this example are as follows.

### (Film Deposition Conditions and Reforming Conditions)

Deposition temperature: 450° C.
Processing pressure: 533.29 Pa (4 Torr)
Rotation of turntable 2: 20 rpm
High frequency power: 1200 W

### (Evaluation Results)

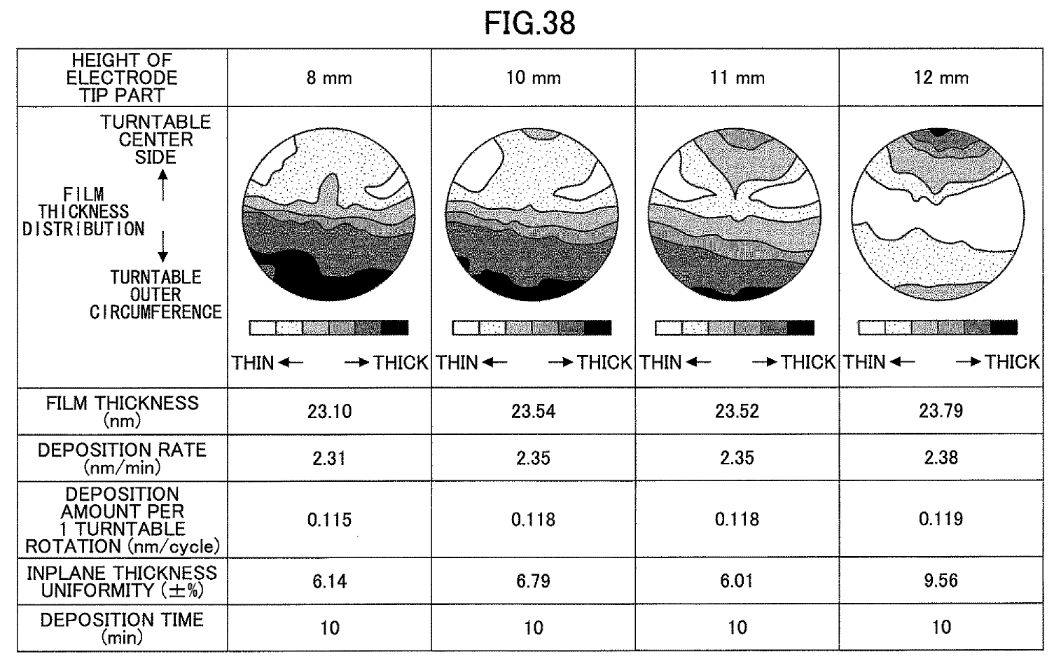

As illustrated in FIG. 38, it was found that film thickness of the thin film in the radial direction of, the turntable 2 can be adjusted by adjusting the height of the distal end portion of the plasma generating portion 80. Further, in this example, the most uniform film thickness was obtained in the radial direction of the turntable 2 when the height H was 11 mm. As illustrated in FIG. 38, reforming intensity increases as the film thickness decreases.

### Ninth Example

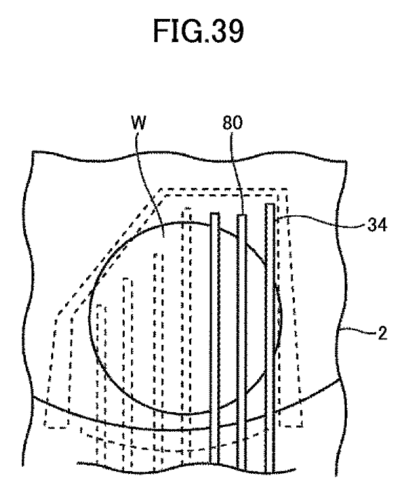

As illustrated in FIG. 39, the reforming process was performed using 2 plasma generating portions in which the plasma generation portions 80 were positioned in the first position and the second position from the upstream side of the turntable 2. In this case, the distance F between adjacent electrodes 36 was set to 45 mm. Further, the height H of the distal end portion of the plasma generating portion 80 positioned at the first position and the second position are 14 mm and 12 mm, respectively. The distance between the wafer W situated towards the base end side of the plasma generating portion 80 and the distal end portion of the plasma generating portion 80 positioned at the first position and the second position were 10.5 mm and 10 mm, respectively. The test conditions were as follows. After a test was performed once, the test was performed again under the same conditions after detaching the plasma generating portions 80 and reattaching the detached plasma generation portions 80.

### (Test Conditions)

Film deposition temperature: 350° C.
Processing pressure: 533.29 Pa (4 Torr)
First process gas flow rate: 600 sccm
Second process gas (O₃) flow rate: 300 g/Nm₃ (O₂: 6 slm)
Gas for reforming process (O₂): 10 slm
Rotation of turntable: 20 rpm
High frequency power: 800 W

### (Test Results)

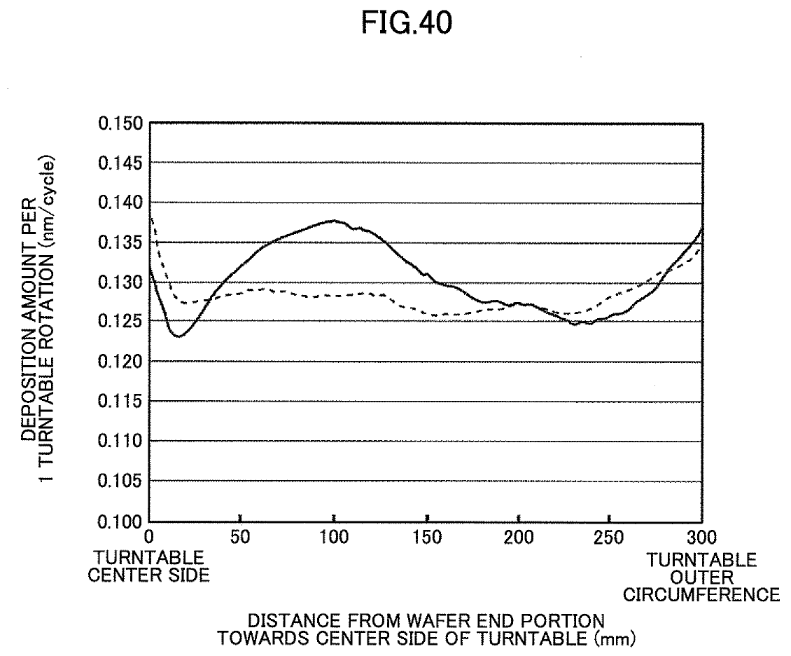

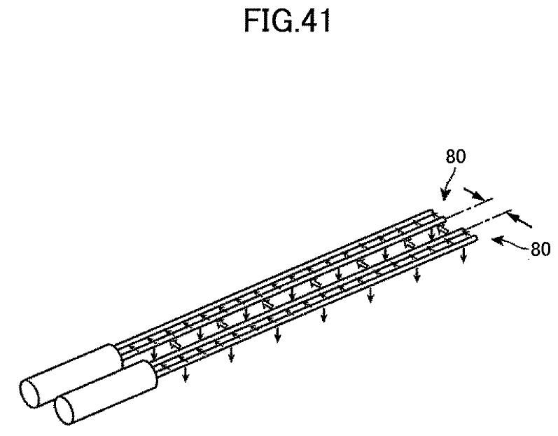

AS illustrated in FIG. 40, although the tests were performed under the conditions, the results of the film deposition rate (deposition amount per 1 turntable rotation) were different (i.e. reproducibility was not obtained). According to another test performed by visual observation, it was found that the reason for this is because discharge occurring between the adjacent plasma generating portions 80 (as illustrated in FIG. 41) causes deficiency of plasma supplied towards the wafer W. According to the visual observation, the range between the center side of the turntable 2 and the distance of approximately 100 mm where film thickness increases in FIG. 40 corresponds to a range at which the discharge between the adjacent plasma generating portions occurs. Accordingly, it is preferable that the adjacent plasma generating portions are sufficiently spaced apart from each other (distance A).

### Tenth Example

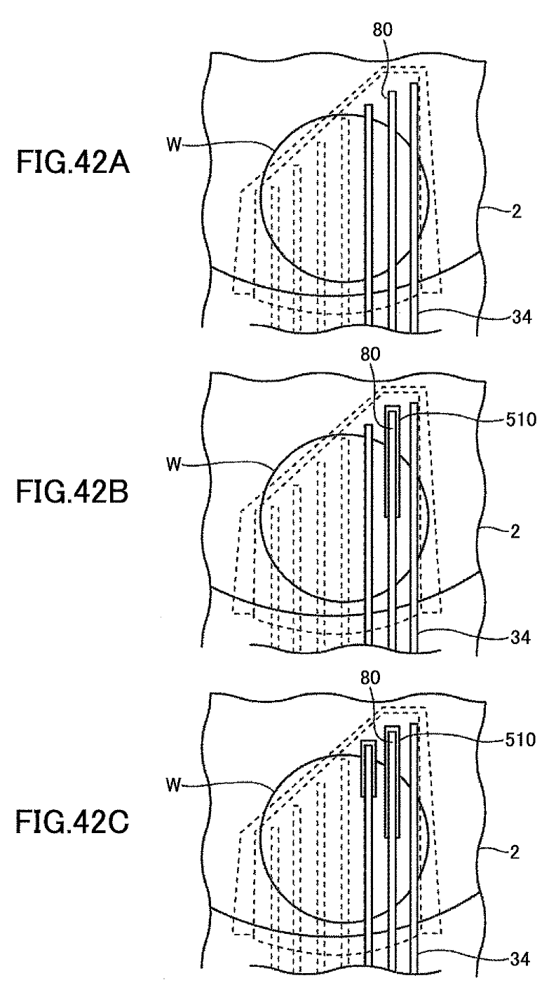

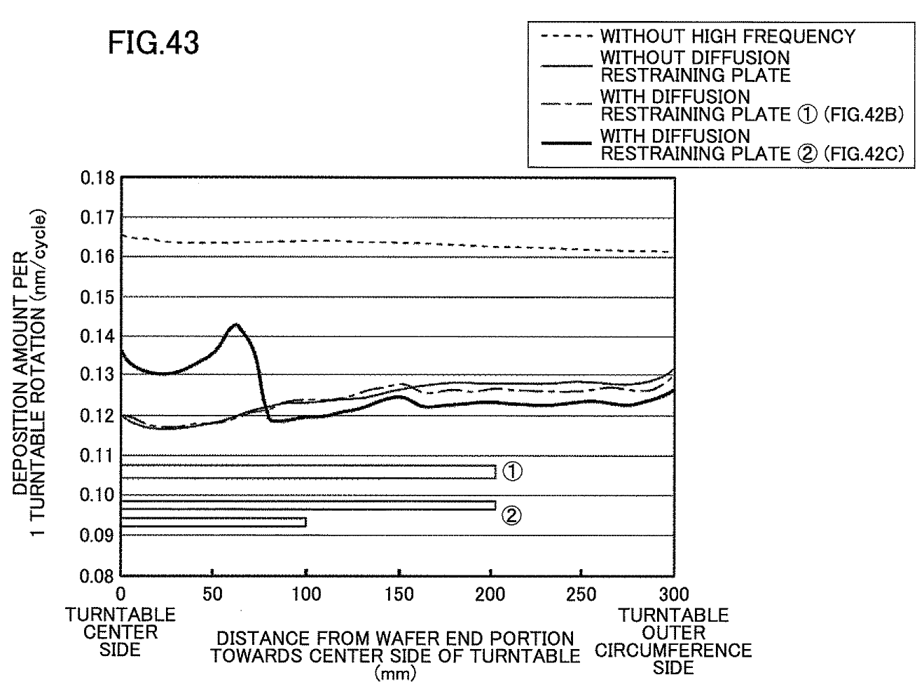

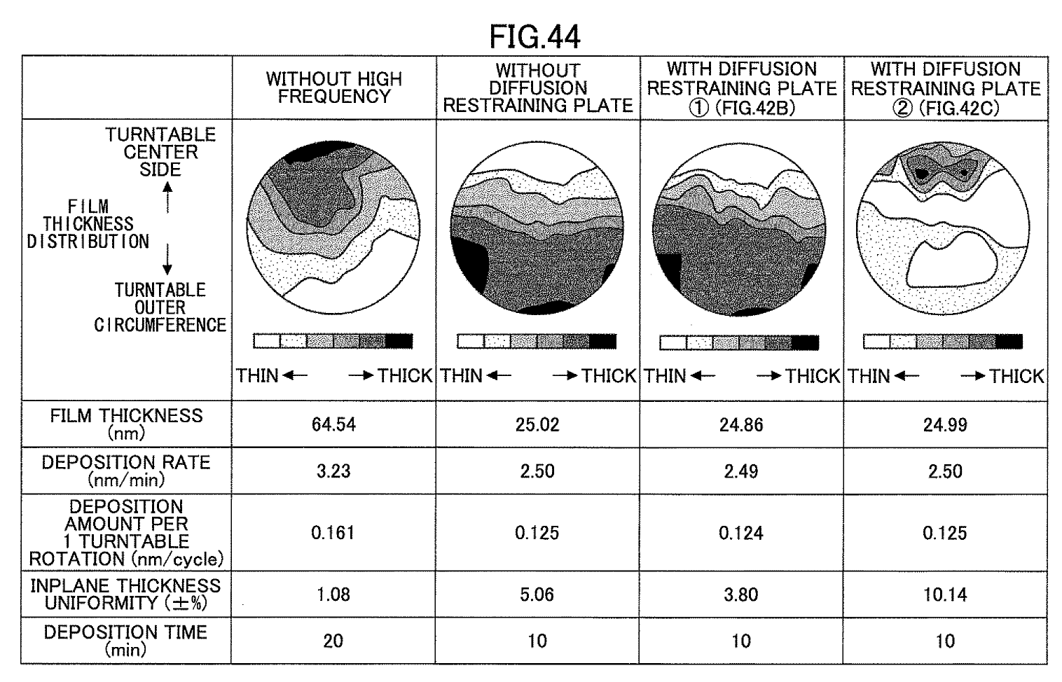

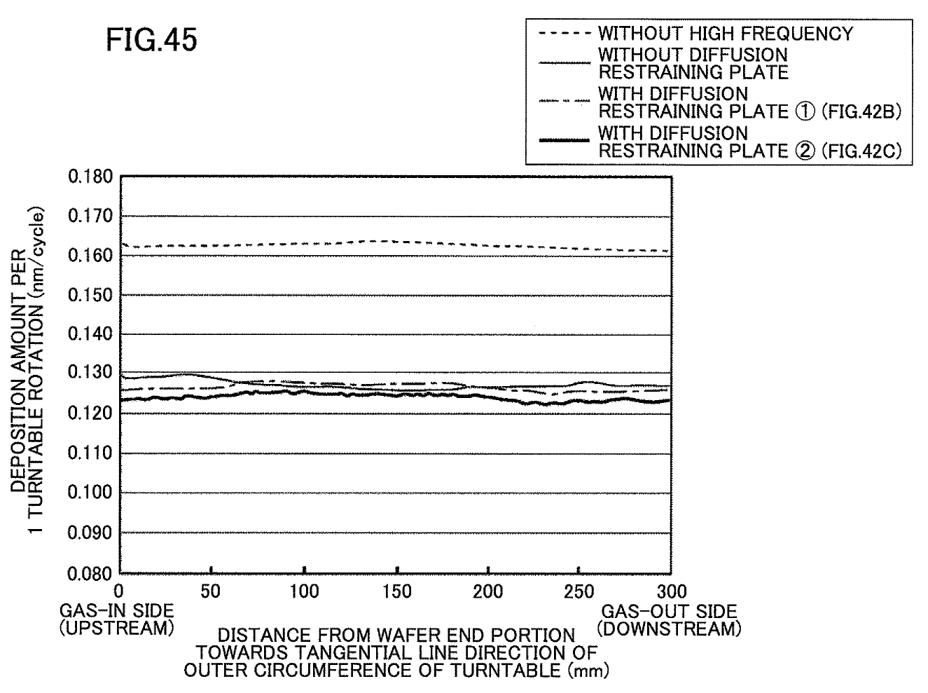

In this example, a film property of the thin film obtained by providing/not providing the diffusion restraining plate was tested. As illustrated in FIG. 42A, the plasma generating portions 80 were provided in the first position and the second position from the upstream side of the turntable 2. The test was performed in a case of providing the diffusion restraining plate 510 having a length G of 200 mm at the first position (FIG. 42B) and in a case of providing the diffusion restraining plates 510 having a length G of 200 mm and 100 mm at the first and second positions, respectively (FIG. 42C). The test conditions were as follows.

### (Test Conditions)

Film deposition temperature: 350° C. (450° C. where no high frequency power is applied)
Processing pressure: 533.29 Pa (4 Torr)
First reaction gas flow rate: 600 sccm
Second reaction gas (O₃) flow rate: 300 g/Nm₃ (O₂: 6 slm)
Gas for reforming process (O₂): flow rate: 10 slm
Rotation of turntable 2: 20 rpm
High frequency power: 1200 W

### (Test Results)

As illustrated in FIG. 43, in comparison with a case of not supplying high frequency power (not performing a reforming process), a thinner dense thin film can be obtained by performing the reforming process using the plasma generating portions 80. Further, in the case of providing the diffusion restraining plates 510 to both plasma generating portions 80 (FIG. 42C), film thickness increases at the distal end side (towards the center of the turntable 2) of the plasma generating portion 80 than at the base end side (outer circumferential side of the turntable 2) of the plasma generating portion 80. Accordingly, with the configuration of FIG. 42C, reforming effect becomes weaker at the distal end side of the plasma generating portion 80 compared to the base end side of the plasma generating portion 80. Thus, it was found that the diffusion restraining plates 510 prevent diffusion of plasma towards the wafer W. In this case, even where the reforming effect becomes weaker towards the center of the turntable 2, film thickness decreases compared to the case of not supplying high frequency power. This is because the radicals contained in the plasma roundabouts the side of the diffusion restraining plates 510 and reaches the wafer W or because plasma diffuses towards the center portion of the turntable 2 from the peripheral edge portion of the turntable 2.

Further, at an area closer towards an outer circumferential side of turntable than the diffusion restraining plate 510 in the radial direction of the turntable 2, the film thickness decreases and the degree of reforming becomes stronger compared to the case of not providing the diffusion restraining plates 510. This is because the plasma generated in the area where the diffusion restraining plate 510 is provided roundabouts to the outer circumferential side of the turntable 2.

In the case of providing the diffusion restraining plate 510 to one of the two plasma generating portions 50 situated in the upstream side of the turntable 2 (FIG. 42B), the film thickness relative to the radial direction of the turntable 2 was substantially the same as the case of providing no diffusion restraining plate (FIG. 42A). This is because the reforming process was sufficiently performed by the plasma generating portion 80 having no diffusion restraining plate 510 provided thereto.

The results of distribution of film thickness and film thickness relative to the radial direction of the turntable 2 in this example are shown in FIG. 44. Thus, it was found that the distribution of film thickness (degree of reforming) relative to the radial direction of the turntable 2 can be adjusted by providing the diffusion restraining plate 510. Further, as illustrated in FIG. 45, the film thicknesses towards the tangential line direction of the turntable 2 were uniform for all of the cases.

With the plasma process apparatus according to the above-described embodiments of the present invention, a plasma process can be performed achieving high uniformity in the in-plane direction of each one of plural substrates placed and rotated on a turntable.

More specifically, in a case of performing a plasma process on plural substrates placed and rotated on a turntable by using the plasma process apparatus according to the above-described embodiments of the present invention, high uniformity can be attained in the in-plane direction of each of the substrates by using plasma generating portions positioned in a manner opposite to a passing area of a substrate receiving area, extending in a rod-like manner from the center side of the turntable to the outer circumferential side of the turntable, and being spaced apart from each other in the circumferential direction of the vacuum chamber.

While the present invention has been described in reference to the foregoing embodiments, the present invention is not limited to the disclosed embodiments, but may be modified or altered within the scope of the accompanying claims.

What is claimed is:

1. A plasma process apparatus for processing a substrate by using plasma, the plasma process apparatus comprising:
a vacuum chamber in which the processing of the substrate is performed;
a turntable provided inside the vacuum chamber, the turntable having at least one substrate receiving area on which the substrate is received;
a rotation mechanism that rotates the turntable;
a gas supplying part that supplies a plasma generation gas to the substrate receiving area;
a main plasma generating part that ionizes the plasma generation gas by applying energy to the plasma generation gas, the main plasma generating part being provided in a position opposite to a passing area of the substrate receiving area and extending in a rod-like manner from a center portion of the turntable to an outer circumferential portion of the turntable;
an auxiliary plasma generating part that compensates for insufficient plasma of the main plasma generating part, the auxiliary plasma generating part being separated from the main plasma generating part in a circumferential direction of the vacuum chamber; and
an evacuating part that evacuates the inside of the vacuum chamber.

2. The plasma process apparatus as claimed in claim 1, further comprising a reaction gas supplying part that performs film deposition on the substrate, wherein the reaction gas supplying part is separated from the main plasma generating part and the auxiliary plasma generating part in the circumferential direction of the vacuum chamber.

3. The plasma process apparatus as claimed in claim 1, wherein the vacuum chamber includes a plurality of process areas arranged at angular intervals along a circumferential direction of the turntable and a separation area provided between the plural process areas, wherein the reaction gas supplying part is configured to supply different types of reaction gases to the plural process areas, wherein a separation gas is supplied to the separation area for preventing the different types of reaction gases from intermixing, wherein the film deposition is performed by sequentially supplying the different types of reaction gases.

4. The plasma process apparatus as claimed in claim 1, further comprising a cover body that covers the main plasma generating part, the auxiliary plasma generating part, and the gas supplying part so that gas from an upstream side relative to a rotation direction of the turntable flows between the main and auxiliary plasma generating parts and a ceiling portion provided above the main and auxiliary plasma generating parts.

5. The plasma process apparatus as claimed in claim 4, further comprising a gas flow control part extending from a lower side edge of the cover body in a longitudinal direction and being bent in a flange-like shape towards the upstream side relative to the rotation direction of the turntable.

6. The plasma process apparatus as claimed in claim 1, wherein the auxiliary plasma generating part is configured to compensate for insufficient plasma of the main plasma generating part at an outer edge side of the substrate receiving area.

7. The plasma process apparatus as claimed in claim 6, further comprising a high frequency power source shared by the main plasma generating part and the auxiliary plasma generating part for supplying power used for generating plasma, wherein the auxiliary plasma generating part includes a diffusion restraining part provided to a lower part of the auxiliary plasma generating part for preventing gas from diffusing to the substrate receiving area at the center portion of the turntable.

8. The plasma process apparatus as claimed in claim 1, wherein at least one of the main plasma generating part and the auxiliary plasma generating part is hermetically inserted to a side wall of the vacuum chamber at the outer circumferential portion of the turntable, wherein at least one of the main plasma generating part and the auxiliary plasma generating part includes an inclination adjustment mechanism provided to a base end part of the one of the main plasma generating part and the auxiliary plasma generating part for inclining the one of the main plasma generating part and the auxiliary plasma generating part in a longitudinal direction of the one of the main plasma generating part and the auxiliary plasma generating part with respect to a surface of the substrate on the substrate receiving area.

9. The plasma process apparatus as claimed in claim 1, wherein the main plasma generating part and the auxiliary plasma generating part includes parallel electrodes extending in a longitudinal direction of the main plasma generating part and the auxiliary plasma generating part for generating a capacitive coupled plasma.

10. The plasma process apparatus as claimed in claim 1, wherein the main plasma generating part and the auxiliary plasma generating part includes a rod-like antenna for generating an inductive coupled plasma.
